(19) United States
(12) Patent Application Publication
(10) Pub. No.: US 2024/0057403 A1
(43) Pub. Date: Feb. 15, 2024

(54) DISPLAY DEVICE

(71) Applicant: SEMICONDUCTOR ENERGY LABORATORY CO., LTD., Atsugi-shi, Kanagawa-ken (JP)

(72) Inventors: Yuichi YANAGISAWA, Atsugi, Kanagawa (JP); Shinya SASAGAWA, Chigasaki, Kanagawa (JP); Takashi HAMADA, Atsugi, Kanagawa (JP)

(21) Appl. No.: 18/266,645

(22) PCT Filed: Dec. 16, 2021
(86) PCT No.: PCT/IB2021/061812

§ 371 Date: Jun. 12, 2023

(30) Foreign Application Priority Data
Dec. 29, 2020 (JP) 2020-219828

(51) Int. Cl. H10K 59/124

(52) U.S. Cl. CPC H10K 59/124

(57) ABSTRACT

A highly reliable display device is provided. The display device includes a transistor over a substrate, a first insulating layer over the transistor, a second insulating layer over the first insulating layer, a plug placed to be embedded in the first insulating layer and the second insulating layer, and a light-emitting element over the second insulating layer. The light-emitting element includes a first conductive layer, an EL layer over the first conductive layer, and a second conductive layer over the EL layer. The plug electrically connects one of a source and a drain of the transistor to the first conductive layer. The second insulating layer has higher capability of inhibiting hydrogen diffusion than the first insulating layer.

### TECHNICAL FIELD

One embodiment of the present invention relates to a display device and a display module. One embodiment of the present invention relates to a method for manufacturing a display device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. Note that in this specification and the like, a semiconductor device generally means a device that can function by utilizing semiconductor characteristics.

### BACKGROUND ART

In recent years, higher-definition display panels have been required. For example, devices for virtual reality (VR), augmented reality (AR), substitutional reality (SR), or mixed reality (MR) have been actively developed in recent years as devices requiring higher-definition display panels.

In addition, examples of a display device that can be applied to a display panel include, typically, a liquid crystal display device, a light-emitting apparatus including a light-emitting element such as an organic EL (Electro Luminescence) element or a light-emitting diode (LED), electronic paper performing display by an electrophoretic method or the like, and the like.

For example, the basic structure of an organic EL element is a structure in which a layer containing a light-emitting organic compound is provided between a pair of electrodes. By applying voltage to this element, light emission can be obtained from the light-emitting organic compound. A display device to which such an organic EL element is applied does not need a backlight that is necessary for a liquid crystal display device or the like; thus, a thin, lightweight, high-contrast, and low-power display device can be achieved. Patent Document 1, for example, discloses an example of a display device using an organic EL element.

### REFERENCE

### Patent Document

[Patent Document 1] Japanese Published Patent Application No. 2002-324673

### SUMMARY OF THE INVENTION

### Problems to be Solved by the Invention

For example, in the above device for VR, AR, SR, or MR that is wearable, a lens for focus adjustment needs to be provided between eyes and the display panel. Since part of a screen is enlarged by the lens, the low definition of the display panel might cause a problem of weak sense of reality and immersion.

The display panel also needs to have high color reproducibility. In particular, in the above device for VR, AR, SR, or MR, the use of a display panel that has high color reproducibility enables display with a color close to the color of an actual object and can increase the sense of reality and immersion.

An object of one embodiment of the present invention is to provide a display device with extremely high definition. Another object of one embodiment of the present invention is to provide a highly reliable display device. Another object of one embodiment of the present invention is to provide a display device in which high color reproducibility is achieved. Another object of one embodiment of the present invention is to provide a display device with high luminance. Another object of one embodiment of the present invention is to provide a method for manufacturing the above display device.

Note that the description of these objects does not preclude the presence of other objects. Note that in one embodiment of the present invention, there is no need to achieve all these objects. Note that objects other than these can be identified from the description of the specification, the drawings, the claims, and the like.

### Means for Solving the Problems

One embodiment of the present invention is a display device that includes a transistor over a substrate, a first insulating layer over the transistor, a second insulating layer over the first insulating layer, a plug placed to be embedded in the first insulating layer and the second insulating layer, and a light-emitting element over the second insulating layer. The light-emitting element includes a first conductive layer, an EL layer over the first conductive layer, and a second conductive layer over the EL layer. The plug electrically connects one of a source and a drain of the transistor to the first conductive layer. The second insulating layer has higher capability of inhibiting hydrogen diffusion than the first insulating layer.

In addition, in the above structure, the second insulating layer preferably contains nitrogen and silicon.

In addition, in the above structure, it is preferable that the second insulating layer include a first layer and a second layer over the first layer, that the first layer contain nitrogen and silicon, and that the second layer contain oxygen and aluminum.

In addition, in the above structure, it is preferable that the second insulating layer include a first layer and a second layer over the first layer, that the first layer contain nitrogen and silicon, and that the second layer contain oxygen and hafnium.

In addition, in the above structure, it is preferable that a third insulating layer be placed to cover the light-emitting element and that the third insulating layer have higher capability of inhibiting hydrogen diffusion than the first insulating layer.

In addition, in the above structure, it is preferable that the third insulating layer be in contact with the second insulating layer in a region that is not overlapped with the light-emitting element.

In addition, in the above structure, it is preferable that the third insulating layer include a third layer and a fourth layer over the third layer, that the third layer contain oxygen and aluminum, and that the fourth layer contain nitrogen and silicon.

In addition, in the above structure, it is preferable that the EL layer cover a side surface of the first conductive layer.

In addition, in the above structure, it is preferable that an insulator be placed between the EL layer and the first conductive layer, that the insulator have an opening over the first conductive layer, and the EL layer be in contact with the first conductive layer in the opening.

In addition, in the above structure, it is preferable that the first conductive layer have a property of reflecting visible light. Furthermore, in the above structure, it is preferable that the second conductive layer have a property of transmitting and reflecting visible light.

In addition, in the above structure, it is preferable that the substrate be a silicon substrate and that the transistor include silicon in a channel formation region.

In addition, in the above structure, it is preferable that an oxide semiconductor film be provided over the substrate and that the transistor include the oxide semiconductor film in a channel formation region.

### Effect of the Invention

According to one embodiment of the present invention, a display device with extremely high definition can be provided. Alternatively, a highly reliable display device can be provided. Alternatively, a display device in which high color reproducibility is achieved can be provided. Alternatively, a display device with high luminance can be provided. Alternatively, a method for manufacturing the above display device can be provided.

Note that the description of these effects does not preclude the presence of other effects. Note that one embodiment of the present invention does not necessarily have all the effects. Note that effects other than these can be identified from the description of the specification, the drawings, the claims, and the like.

### BRIEF DESCRIPTION OF THE DRAWINGS

FIG. 1A to FIG. 1C are diagrams each illustrating a structure example of a display device.

FIG. 2A and FIG. 2B are diagrams each illustrating a structure example of the display device.

FIG. 3A and FIG. 3B are diagrams each illustrating a structure example of the display device.

FIG. 4A and FIG. 4B are diagrams each illustrating a structure example of the display device.

FIG. 5A to FIG. 5E are diagrams illustrating an example of a method for manufacturing the display device.

FIG. 6A to FIG. 6D are diagrams illustrating the example of the method for manufacturing the display device.

FIG. 7 is a diagram illustrating a structure example of a display device.

FIG. 8 is a diagram illustrating a structure example of a display device.

FIG. 9 is a diagram illustrating a structure example of a display device.

FIG. 10 is a diagram illustrating a structure example of a display device.

FIG. 11A and FIG. 11B are diagrams illustrating a structure example of a display module.

FIG. 12A and FIG. 12B are circuit diagrams illustrating an example of a display device.

FIG. 13A and FIG. 13C are circuit diagrams each illustrating an example of a display device.

FIG. 13B is a timing chart showing an operation example of the display device.

FIG. 14A and FIG. 14B are diagrams each illustrating a structure example of an electronic device.

FIG. 15A and FIG. 15B are diagrams each illustrating a structure example of an electronic device.

FIG. 16A to FIG. 16C are diagrams each illustrating a structure example of a display device.

FIG. 17A and FIG. 17B are diagrams each illustrating a structure of a sample in this example.

FIG. 18A and FIG. 18B are diagrams showing results of this example.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the present invention described below, the same reference numerals are used in common for the same portions or portions having similar functions in different drawings, and a repeated description thereof is omitted. Moreover, similar functions are denoted by the same hatch pattern and are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification are used in order to avoid confusion among components and do not limit the number.

### Embodiment 1

In this embodiment, a display device according to one embodiment of the present invention and a method for manufacturing the display device will be described.

The display device according to one embodiment of the present invention includes light-emitting elements (also referred to as light-emitting devices) that emit light with different colors. The light-emitting element includes a lower electrode, an upper electrode, and a light-emitting layer (also referred to as a layer containing a light-emitting compound) therebetween. As the light-emitting element, an electroluminescent element such as an organic EL element or an inorganic EL element is preferably used. Alternatively, a light-emitting diode (LED) may be used.

As the EL element, an OLED (Organic Light Emitting Diode), a QLED (Quantum-dot Light Emitting Diode), or the like can be used. Examples of a light-emitting compound (also referred to as a light-emitting substance) contained in the EL element include a substance that exhibits fluorescence (a fluorescent material), a substance that exhibits phosphorescence (a phosphorescent material), an inorganic compound (a quantum dot material or the like), a substance that exhibits thermally activated delayed fluorescence (a thermally activated delayed fluorescent (TADF) material), and the like.

As the light-emitting substance, a substance that exhibits a light emission color of blue, purple, bluish purple, green, yellowish green, yellow, orange, red, or the like is used as appropriate. Alternatively, a substance that emits near-infrared light may be used.

The light-emitting layer may contain one or more kinds of compounds (a host material and an assist material) in addition to the light-emitting substance (guest material). As the host material and the assist material, one or more kinds of substances having a larger energy gap than the light-emitting substance (guest material) can be selected and used. As the host material and the assist material, compounds that form an exciplex are preferably used in combination. To form an exciplex efficiently, it is particularly preferable to combine a compound that easily accepts holes (a hole-transport material) and a compound that easily accepts electrons (an electron-transport material).

Either a low molecular compound or a high molecular compound can be used for the light-emitting element, and an inorganic compound (a quantum dot material or the like) may be contained.

In the display device according to one embodiment of the present invention, it is possible to form light-emitting elements with different colors separately with extremely high accuracy. Thus, a display device with higher definition than a conventional display device can be achieved. For example, the display device preferably has extremely high definition in which pixels including one or more light-emitting elements are arranged with a definition greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

More specific structure examples and a manufacturing method example will be described below with reference to drawings.

### Structure Example 1

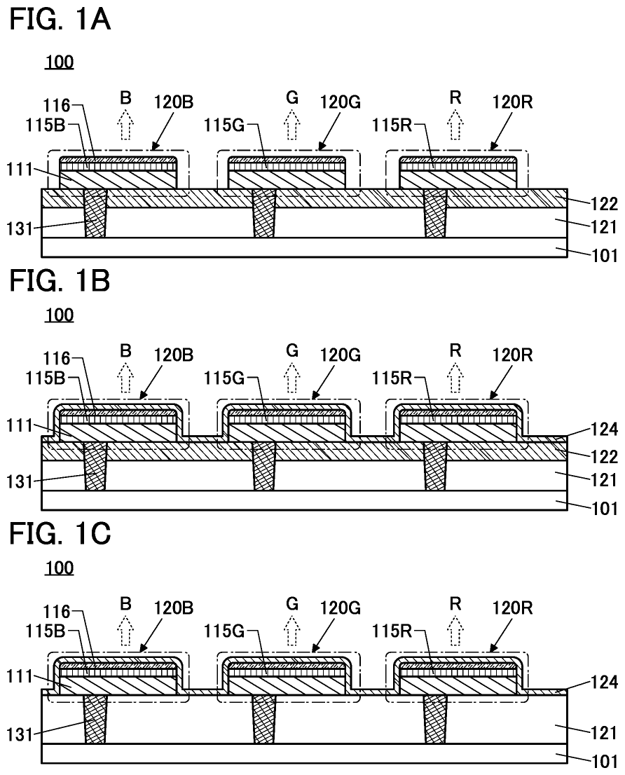

FIG. 1A is a schematic cross-sectional view illustrating a display device according to one embodiment of the present invention. A display device 100 includes a light-emitting element 120R, a light-emitting element 120G, and a light-emitting element 120B. The light-emitting element 120R is a light-emitting element that exhibits a red color, the light-emitting element 120G is a light-emitting element that exhibits a green color, and the light-emitting element 120B is a light-emitting element that exhibits a blue color.

Note that in the following description common to the light-emitting element 120R, the light-emitting element 120G, and the light-emitting element 120B, the alphabets are omitted from the reference numerals and the term “light-emitting element 120” is used in some cases. In addition, similarly, for an EL layer 115R, an EL layer 115G, and an EL layer 115B to be described later, the term “EL layer 115” is used in some cases. The EL layer 115R is included in the light-emitting element 120R. Similarly, the EL layer 115G is included in the light-emitting element 120G, and the EL layer 115B is included in the light-emitting element 120B. Furthermore, similarly, for a conductive layer 114R, a conductive layer 114G, and a conductive layer 114B to be described later, the term “conductive layer 114” is used in some cases. The conductive layer 114R is included in the light-emitting element 120R. Similarly, the conductive layer 114G is included in the light-emitting element 120G, and the conductive layer 114B is included in the light-emitting element 120B.

The light-emitting element 120 includes a conductive layer 111 that functions as a lower electrode, the EL layer 115, and a conductive layer 116 that functions as an upper electrode. The conductive layer 111 has a property of reflecting visible light. The conductive layer 116 has a property of transmitting and reflecting visible light. Alternatively, the conductive layer 116 has a semi-transmissive property and a semi-reflective property with respect to visible light in some cases. The EL layer 115 contains a light-emitting compound. The EL layer 115 contains at least a light-emitting layer included in the light-emitting element 120.

As the light-emitting element 120, it is possible to use an electroluminescent element having a function of emitting light in accordance with current flowing through the EL layer 115 when a potential difference is applied between the conductive layer 111 and the conductive layer 116. In particular, an organic EL element using a light-emitting organic compound is preferably used for the EL layer 115. In addition, the light-emitting element 120 is preferably an element emitting white light, which has two or more peaks in the visible light region of an emission spectrum.

The components over the conductive layer 111 have a property of reflecting visible light.

The display device 100 includes a substrate 101 provided with a semiconductor circuit and the light-emitting element 120 over the substrate 101. In addition, the display device 100 illustrated in FIG. 1A includes an insulating layer 121 over the substrate 101, an insulating layer 122 over the insulating layer 121, and the light-emitting element 120 over the insulating layer 122.

A circuit substrate provided with a transistor, a wiring, and the like can be used as the substrate 101. Note that in the case where a passive matrix method or a segment method can be employed, an insulating substrate such as a glass substrate can be used as the substrate 101. In addition, the substrate 101 is a substrate provided with a circuit for driving each light-emitting element (also referred to as a pixel circuit). Furthermore, the substrate 101 may be provided with a semiconductor circuit that functions as a driver circuit for driving the pixel circuit. A semiconductor element included in such a pixel circuit or semiconductor circuit may be formed using a semiconductor substrate such as a single crystal silicon substrate or may be formed using an oxide semiconductor film. More specific structure examples of the substrate 101 will be described later.

In the display device 100 illustrated in FIG. 1A, the substrate 101 is electrically connected to the conductive layer 111 of the light-emitting element 120 through a plug 131. The plug 131 is formed to be embedded in an opening provided in the insulating layer 121 and the insulating layer 122. The conductive layer 111 is formed over the insulating layer 122. The conductive layer 111 is provided over the plug 131. The conductive layer 111 is electrically connected to the plug 131. In addition, the conductive layer 111 is preferably in contact with a top surface of the plug 131. Alternatively, a structure may be employed in which the conductive layer 111 is in contact with a top surface of the insulating layer 122.

The insulating layer 122 preferably functions as a barrier insulating film against impurities such as hydrogen. The insulating layer 122 has a function of inhibiting diffusion of at least one of hydrogen and a substance bonded with hydrogen (for example, water (H₂O) or the like). Thus, the insulating layer 122 is regarded as an insulating layer with higher capability of inhibiting diffusion of at least one of hydrogen and a substance bonded with hydrogen than the insulating layer 121. Alternatively, the insulating layer 122 preferably has a function of capturing or fixing (also referred to as gettering) at least one of hydrogen and a substance bonded with hydrogen. Thus, the insulating layer 122 preferably has higher capability of capturing or fixing at least one of hydrogen and a substance bonded with hydrogen than the insulating layer 121. Alternatively, the insulating layer 122 may function as a barrier insulating film against oxygen.

Note that in this specification, a barrier insulating film refers to an insulating film having a barrier property. A barrier property in this specification means a function of inhibiting diffusion of a particular substance (also referred to as having low permeability). Alternatively, a barrier property in this specification refers to a function of capturing or fixing (also referred to as gettering) a particular substance.

In the display device according to one embodiment of the present invention, providing a barrier insulating film against water, hydrogen, or the like below a light-emitting element can inhibit diffusion of impurities such as water or hydrogen that is contained in an interlayer insulating film and a semiconductor circuit such as a pixel circuit provided below the light-emitting element. Thus, degradation of the light-emitting element can be prevented. In addition, in the display device according to one embodiment of the present invention, a barrier insulating film against oxygen may be provided below the light-emitting element. Accordingly, degradation of the light-emitting element due to diffusion of excess oxygen can be prevented.

In addition, in the case where an oxide semiconductor is provided for the semiconductor circuit, it is possible to inhibit diffusion of impurities such as water or hydrogen that is contained in the light-emitting element and an interlayer insulating film over the light-emitting element into the oxide semiconductor. Accordingly, the decrease in electrical characteristics and reliability of an element that includes the oxide semiconductor can be prevented.

Accordingly, in one embodiment of the present invention, it is possible to inhibit diffusion of impurities into a light-emitting element and a semiconductor circuit such as a pixel circuit; thus, a highly reliable display device can be provided.

In addition, as illustrated in FIG. 1B, an insulating layer 124 may be further provided to cover the light-emitting element 120. Like the insulating layer 122, the insulating layer 124 also functions as a barrier insulating film against impurities such as water or hydrogen. Providing the insulating layer 124 can inhibit diffusion of impurities such as water or hydrogen from an interlayer insulating film provided over the light-emitting element 120 into the light-emitting element 120 and the semiconductor circuit of the substrate 101. Alternatively, like the insulating layer 122, the insulating layer 124 may also function as a barrier insulating film against oxygen. Accordingly, degradation of the light-emitting element 120 due to diffusion of excess oxygen into the light-emitting element 120 can be inhibited.

At this time, it is preferable to employ a structure where the insulating layer 124 is in contact with the insulating layer 122 in a region that is not overlapped with the conductive layer 111. Here, the insulating layer 124 is in contact with a top surface and side surfaces of the conductive layer 116, side surfaces of the EL layer 115, and side surfaces of the conductive layer 111. Accordingly, the light-emitting element 120 is surrounded by the insulating layer 124 and the insulating layer 122, so that diffusion of impurities such as water or hydrogen into the light-emitting element 120 can be further inhibited.

Note that in the case where only the insulating layer 124 can sufficiently inhibit impurity diffusion, a structure may be employed in which the insulating layer 122 is not provided and only the insulating layer 124 is provided, as illustrated in FIG. 1C. In that case, the insulating layer 124 and the conductive layer 111 are provided in contact with the insulating layer 121.

In the display device 100 illustrated in FIG. 1A to FIG. 1C, the EL layers 115 and the conductive layers 116 are isolated between the adjacent light-emitting elements with different colors. Thus, leakage current flowing through the EL layer 115 between the adjacent light-emitting elements with different colors can be prevented. Accordingly, light emission caused by the leakage current can be inhibited, and display with high contrast can be achieved. In addition, a highly conductive material can be used for the EL layer 115 even in the case of increased definition, so that the range of material choices can be broadened, and the improvement in efficiency, the reduction in power consumption, and the improvement in reliability are facilitated.

Note that in the display device 100, it is preferable that the EL layer 115 and the conductive layer 116 be processed to be continuous without any division between pixels that exhibit the same color. For example, the EL layer 115 and the conductive layer 116 can be processed into a stripe shape. Thus, the conductive layers 116 in all the light-emitting elements can be supplied with a predetermined potential without being brought into a floating state.

For each of the EL layer 115 and the conductive layer 116, an island-shaped pattern may be formed by deposition using a metal mask or a shadow mask such as an FMM (a fine metal mask or a high-definition metal mask). In particular, it is preferable to use a processing method that does not use a metal mask or an FMM. As such a processing method, a photolithography method can be typically used. Alternatively, a formation method such as a nanoimprinting method or a sandblasting method can be used. Note that in this specification and the like, a device manufactured using a metal mask or an FMM (a fine metal mask or a high-definition metal mask) is sometimes referred to as a device having an MM (a metal mask) structure. In addition, in this specification and the like, a device manufactured without using a metal mask or an FMM is sometimes referred to as a device having an MML (metal maskless) structure.

Thus, the MML (metal maskless) structure enables formation of an extremely minute pattern, so that the definition and aperture ratio can be improved compared to the MM (metal mask) structure.

As illustrated in FIG. 1A to FIG. 1C, a structure may be employed in which end portions of the EL layer 115 are substantially aligned with end portions of the conductive layer 111. Alternatively, a structure may be employed in which end portions of the conductive layer 116 are substantially aligned with the end portions of the conductive layer 111. Alternatively, a structure may be employed in which one of the end portions of the EL layer 115 is positioned on an outer side of the conductive layer 111 and the other of the end portions of the EL layer 115 is substantially aligned with the end portion of the conductive layer 111. Alternatively, a structure may be employed in which one of the end portions of the conductive layer 116 is positioned on an outer side of the conductive layer 111 and the other of the end portions of the conductive layer 116 is substantially aligned with the end portion of the conductive layer 111.

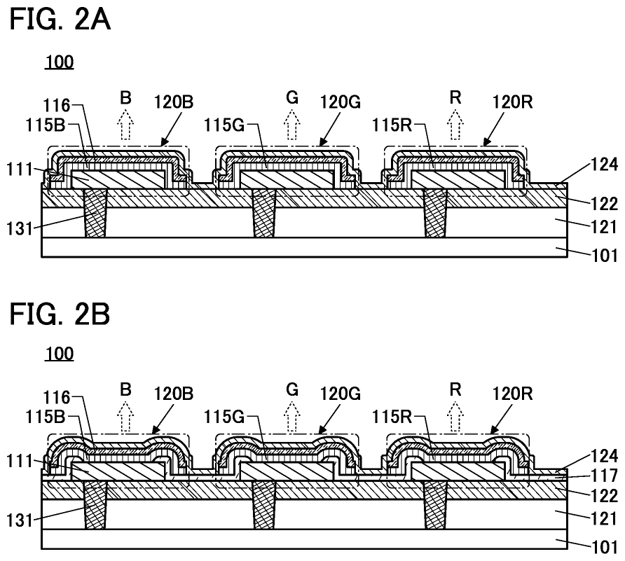

The conductive layer 116 is provided so that at least short-circuit between the conductive layer 116 and the conductive layer 111 does not occur. For example, as illustrated in FIG. 2A, in the cross section of the display device 100, the end portions of the EL layer 115 may be positioned on outer sides of the end portions of the conductive layer 111. The end portions of the EL layer 115 cover the end portions of the conductive layer 111. When the end portions of the EL layer 115 are positioned on outer sides of the end portions of the conductive layer 111, short-circuit between the conductive layer 111 and the conductive layer 116 can be inhibited. In addition, as illustrated in FIG. 2A, in the cross section of the display device 100, the end portions of the conductive layer 116 may be positioned on outer sides of the end portions of the conductive layer 111.

Furthermore, as illustrated in FIG. 2B, a structure may be employed in which an insulator 117 that covers the end portions of the conductive layer 111 is provided. The insulator 117 can also be referred to as a bank, a partition, a barrier, a wall, or the like. The insulator 117 is provided so that a top surface of the conductive layer 111 is exposed. When the insulator 117 is provided, the short-circuit between the conductive layer 111 and the conductive layer 116 can be inhibited.

Note that as in FIG. 1B, a structure where the insulating layer 122 and the insulating layer 124 are provided is illustrated in each of FIG. 2A and FIG. 2B; however, the present invention is not limited thereto, and a structure similar to that illustrated in FIG. 1A or FIG. 1C may be employed.

### [Light-Emitting Element]

As a light-emitting element that can be used as the light-emitting element 120, a self-luminous element can be used, and an element whose luminance is controlled by current or voltage is included in the category. For example, an LED, an organic EL element, an inorganic EL element, or the like can be used. In particular, an organic EL element is preferably used.

The light-emitting element has a top-emission structure, a bottom-emission structure, a dual-emission structure, or the like. A conductive film that transmits visible light is used as an electrode through which light is extracted. In addition, a conductive film that reflects visible light is preferably used as an electrode through which light is not extracted.

In one embodiment of the present invention, in particular, it is possible to suitably use a light-emitting element having a top-emission structure where light is emitted to a side opposite to a formation surface side or a light-emitting element having a dual-emission structure where light is emitted to both a formation surface side and a side opposite to the formation surface side.

The EL layer 115 includes at least a light-emitting layer. In addition to the light-emitting layer, the EL layer 115 may further include layers containing a substance with a high hole-injection property, a substance with a high hole-transport property, a hole-blocking material, an electron-blocking material, a substance with a high electron-transport property, a substance with a high electron-injection property, a substance with a bipolar property (a substance with a high electron-transport property and a high hole-transport property), and the like.

Either a low molecular compound or a high molecular compound can be used for the EL layer 115, and an inorganic compound may be contained. The layers that constitute the EL layer 115 can each be formed by a method such as an evaporation method (including a vacuum evaporation method), a transfer method, a printing method, an inkjet method, or a coating method.

When voltage higher than the threshold voltage of the light-emitting element 120 is applied between a cathode and an anode, holes are injected to the EL layer 115 from the anode side and electrons are injected to the EL layer 115 from the cathode side. The injected electrons and holes are recombined in the EL layer 115 and a light-emitting substance contained in the EL layer 115 emits light.

Here, the EL layer 115 used in the light-emitting element 120B, the EL layer 115 used in the light-emitting element 120G, and the EL layer 115 used in the light-emitting element 120R are referred to as the EL layer 115B, the EL layer 115G, and the EL layer 115R, respectively. The EL layer 115B contains a light-emitting substance that emits B (blue) light. The EL layer 115G contains a light-emitting substance that emits G (green) light. The EL layer 115R contains a light-emitting substance that emits R (red) light. Such a structure in which light emission colors (here, blue (B), green (G), and red (R)) are separately patterned for each of the light-emitting elements is referred to as an SBS (Side By Side) structure in some cases. With such a structure, it is possible to provide a display device whose power consumption is lower than that of a display device having a structure where a coloring layer is provided for a white light-emitting element to obtain colored light.

Note that the light-emitting layer and layers containing a substance with a high hole-injection property, a substance with a high hole-transport property, a substance with a high electron-transport property, a substance with a high electron-injection property, a substance with a bipolar property, and the like may each include an inorganic compound such as a quantum dot or a high molecular compound (an oligomer, a dendrimer, a polymer, or the like). For example, a quantum dot used for the light-emitting layer can function as a light-emitting material.

Note that as a quantum dot material, a colloidal quantum dot material, an alloyed quantum dot material, a core-shell quantum dot material, a core quantum dot material, or the like can be used. Alternatively, a material containing elements belonging to Groups 12 and 16, elements belonging to Groups 13 and 15, or elements belonging to Groups 14 and 16 may be used. Alternatively, a quantum dot material containing an element such as cadmium, selenium, zinc, sulfur, phosphorus, indium, tellurium, lead, gallium, arsenic, or aluminum may be used.

In addition, the conductive film that can be used for the conductive layer 116 or the like and transmits visible light can be formed using, for example, indium oxide, indium tin oxide, indium zinc oxide, zinc oxide, zinc oxide to which gallium is added, or the like. Alternatively, a metal material such as gold, silver, platinum, magnesium, nickel, tungsten, chromium, molybdenum, iron, cobalt, copper, palladium, or titanium; an alloy containing these metal materials; a nitride of these metal materials (e.g., titanium nitride); or the like formed thin enough to have a light-transmitting property can be used. A stacked-layer film of the above materials can be used as a conductive layer. For example, a stacked-layer film or the like of indium tin oxide and an alloy of silver and magnesium is preferably used because conductivity can be increased. Alternatively, graphene or the like may be used.

A conductive film that can be used for the conductive layer 116 and has a semi-transmissive property and a semi-reflective property preferably has reflectance with respect to visible light (e.g., reflectance with respect to light having a specific wavelength within the range of 400 nm to 700 nm) of higher than or equal to 20% and lower than or equal to 80%, preferably higher than or equal to 40% and lower than or equal to 70%. In addition, a conductive film having a reflective property preferably has reflectance with respect to visible light of higher than or equal to 40% and lower than or equal to 100%, preferably higher than or equal to 70% and lower than or equal to 100%. Furthermore, a conductive film having a property of transmitting light preferably has reflectance with respect to visible light of higher than or equal to 0% and lower than or equal to 40%, preferably higher than or equal to 0% and lower than or equal to 30%.

For the conductive layer 111, the conductive film that reflects visible light is preferably used in a portion positioned on the EL layer 115 side. For the conductive layer 111, for example, a metal material such as aluminum, gold, platinum, silver, nickel, tungsten, chromium, molybdenum, iron, cobalt, copper, or palladium or an alloy containing these metal materials can be used. Copper is preferable because of its high reflectance with respect to visible light. Alternatively, aluminum is preferable because an aluminum electrode is easily etched, processing of the aluminum electrode is easy, and the aluminum electrode has high reflectance with respect to visible light and near-infrared light. Alternatively, lanthanum, neodymium, germanium, or the like may be added to the above metal material or alloy. Alternatively, an alloy (an aluminum alloy) containing aluminum and titanium, nickel, or neodymium may be used. Alternatively, an alloy containing silver and copper, palladium, or magnesium may be used. An alloy containing silver and copper is preferable because of its high heat resistance.

Alternatively, the conductive layer 111 may have a structure where a conductive metal oxide film is stacked over the conductive film that reflects visible light. Such a structure can inhibit the conductive film that reflects visible light from being oxidized or corroded. For example, when a metal film or a metal oxide film is stacked in contact with an aluminum film or an aluminum alloy film, oxidation can be inhibited. Examples of a material for the metal film or the metal oxide film include titanium and titanium oxide. Alternatively, the conductive film that transmits visible light and a film containing a metal material may be stacked. For example, a stacked-layer film of silver and indium tin oxide, a stacked-layer film of an alloy of silver and magnesium and indium tin oxide, or the like can be used.

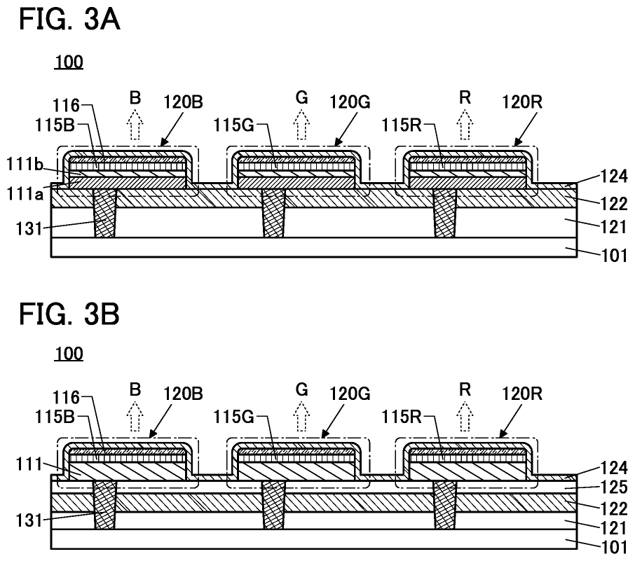

Alternatively, in the conductive layer 111, as illustrated in FIG. 3A, a structure may be employed in which a conductive layer 111a is provided as a conductive layer in a lower layer and a conductive layer 111b is provided over the conductive layer 111a as a conductive layer in an upper layer. In the case of such a structure, it is preferable to use the conductive film that reflects visible light as the conductive layer 111b. In addition, the reflectance of the conductive layer 111a may be lower than that of the conductive layer 111b. A material having high conductivity is used for the conductive layer 111a. Furthermore, a material having excellent processability is used for the conductive layer 111a.

For the conductive layer 111b, it is preferable to employ the material and the structure that can be used for the conductive layer 111.

For example, a metal material such as gold, silver, platinum, magnesium, nickel, tungsten, chromium, molybdenum, iron, cobalt, copper, palladium, titanium, yttrium, zirconium, or tantalum; an alloy containing these metal materials; a nitride of these metal materials (e.g., titanium nitride); or the like can be used for the conductive layer 111a.

In the case where aluminum is used for the conductive layer 111 or the conductive layer 111b, thickness is preferably greater than or equal to 40 nm, further preferably greater than or equal to 70 nm, in which case reflectance with respect to visible light or the like can be sufficiently increased. Alternatively, in the case where silver is used for the conductive layer 111 or the conductive layer 111b, thickness is preferably greater than or equal to 70 nm, further preferably greater than or equal to 100 nm, in which case reflectance with respect to visible light or the like can be sufficiently increased.

For example, it is possible to use tungsten and aluminum or an aluminum alloy for the conductive layer 111a and the conductive layer 111b, respectively. In addition, the conductive layer 111b may have a structure where titanium oxide is provided in contact with an upper portion of aluminum or an aluminum alloy. Alternatively, the conductive layer 111b may have a structure where titanium is provided in contact with an upper portion of aluminum or an aluminum alloy and titanium oxide is provided in contact with an upper portion of titanium.

Alternatively, a material and a structure selected from the materials and the structures that can be used for the conductive layer 111 may be used for each of the conductive layer 111a and the conductive layer 111b.

Alternatively, the conductive layer 111 may have a stacked-layer film of three or more layers.

Note that as in FIG. 1B, a structure where the insulating layer 122 and the insulating layer 124 are provided is illustrated in FIG. 3A; however, the present invention is not limited thereto, and a structure similar to that illustrated in FIG. 1A or FIG. 1C may be employed.

Examples of materials that can be used for the plug 131 include metals such as aluminum, titanium, chromium, nickel, copper, yttrium, zirconium, molybdenum, gold, silver, platinum, magnesium, iron, cobalt, palladium, tantalum, and tungsten; an alloy containing these metal materials; a nitride of these metal materials; and the like. Alternatively, a single layer or a stacked-layer structure including a film containing these materials can be used for the plug 131. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, a three-layer structure in which an aluminum film or a copper film is stacked over a molybdenum film or a molybdenum nitride film and a molybdenum film or a molybdenum nitride film is formed thereover, and the like can be given. Note that an oxide such as indium oxide, tin oxide, or zinc oxide may be used. In addition, copper containing manganese is preferably used because controllability of a shape by etching is increased.

The electrodes included in the light-emitting elements are each formed by an evaporation method or a sputtering method. Alternatively, the electrodes included in the light-emitting elements can be formed by a discharging method such as an inkjet method, a printing method such as a screen printing method, or a plating method.

The insulating layer 121 preferably functions as an interlayer insulating film and has a low dielectric constant. When a material with a low dielectric constant is used for an interlayer film, parasitic capacitance generated between wirings can be reduced. For the insulating layer 121, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

For the insulating layer 122, aluminum oxide, magnesium oxide, hafnium oxide, gallium oxide, indium gallium zinc oxide, silicon nitride, silicon nitride oxide, or the like can be used, for example. As the insulating layer 122 having high capability of inhibiting diffusion of impurities such as hydrogen, silicon nitride (SiNₓ: x is a given number greater than 0) that is deposited by a sputtering method, an ALD method, or the like is preferably used, for example. In that case, the insulating layer 122 is an insulator containing at least nitrogen and silicon.

Alternatively, for the insulating layer 122 having high capability of capturing or fixing impurities such as hydrogen, a metal oxide such as aluminum oxide (AlOₓ: x is a given number greater than 0) or hafnium oxide (HfO_{y}: y is a given number greater than 0) that is deposited by a sputtering method, an ALD method, or the like is preferably used, for example. In the case where aluminum oxide is used for the insulating layer 122, the insulating layer 122 is an insulator containing at least oxygen and aluminum. Alternatively, an oxide with an amorphous structure is preferably used for the insulating layer 122. In such a metal oxide with an amorphous structure, an oxygen atom has a dangling bond and sometimes has a property of capturing or fixing hydrogen with the dangling bond. The use of such a metal oxide with an amorphous structure can capture or fix hydrogen. It is particularly preferable to capture or fix hydrogen included in the insulating layer 121.

Note that although the insulating layer 122 preferably has an amorphous structure, the insulating layer 122 may partly include a crystal region. Alternatively, the insulating layer 122 may have a multilayer structure in which a layer with an amorphous structure and a layer including a crystal region are stacked. For example, the insulating layer 122 may have a stacked-layer structure where a layer with a crystal region, typically, a layer with a polycrystalline structure is formed over a layer with an amorphous structure.

Alternatively, the insulating layer 122 may have a stacked-layer structure. For example, in the case of a two-layer structure, it is possible to employ a structure where an aluminum oxide film or a hafnium oxide film is provided over a silicon nitride film.

In addition, an insulating material that can be used for the insulating layer 122 is also used for the insulating layer 124. Furthermore, the insulating layer 124 may also have a stacked structure. For example, in the case of a two-layer structure, it is possible to employ a structure where an aluminum oxide film or a silicon nitride film that is deposited by a sputtering method is provided over an aluminum oxide film that is deposited by an ALD method. Alternatively, in the case of a three-layer structure, for example, it is possible to employ a structure where an aluminum oxide film deposited by a sputtering method is provided over an aluminum oxide film deposited by an ALD method and a silicon nitride film deposited by a sputtering method is provided over the aluminum oxide film deposited by a sputtering method.

An aluminum oxide film deposited by an ALD method is preferably included in the insulating layer 124. Deposition using an ALD method enables formation of the insulating layer 124 with good coverage with respect to a step formed by the conductive layer 111, the EL layer 115, and the conductive layer 116. Thus, it is possible to prevent the entry of impurities such as water from the above into the light-emitting element 120.

In addition, in the structure illustrated in FIG. 1B, it is preferable that a silicon nitride film be used for the insulating layer 122 and the insulating layer 124 and an aluminum oxide film be provided inside the silicon nitride film. Accordingly, the aluminum oxide film can capture or fix hydrogen that remains inside a region sealed with the silicon nitride film.

In addition, in the structure illustrated in FIG. 1B or the like, a structure is employed in which the insulating layer 122 is in contact with the conductive layer 111 and the insulating layer 124; however, the present invention is not limited thereto. For example, as illustrated in FIG. 3B, a structure may be employed in which an insulating layer 125 is provided between the insulating layer 122, and the conductive layer 111 and the insulating layer 124. An insulating material that can be used for the insulating layer 121 is used for the insulating layer 125. In that case, in the insulating layer 125, a concave portion is sometimes formed on a surface where the conductive layer 111 is not provided. For example, in an etching step at the time of forming the conductive layer 111, a concave portion is formed due to etching of the insulating layer 125.

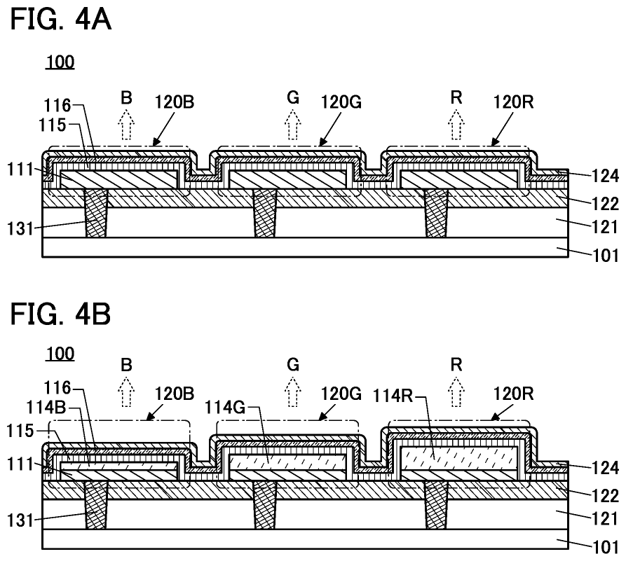

As illustrated in FIG. 4A, a light-emitting substance that emits white light may be employed for the EL layer 115 included in the light-emitting element 120. In that case, as described later, a coloring layer that is overlapped with the light-emitting element 120 is provided. In the case where a light-emitting substance that emits white light is employed for the EL layer 115, the EL layer 115 preferably has a structure that contains two or more kinds of light-emitting substances. White light emission can be obtained by selecting light-emitting substances so that two or more light-emitting substances emit light of complementary colors, for example. For example, it is preferable to contain two or more out of light-emitting substances that emit R (red) light, G (green) light, B (blue) light, Y (yellow) light, O (orange) light, and the like or light-emitting substances that emit light containing spectral components of two or more colors of R, G, and B. In addition, a light-emitting element whose emission spectrum has two or more peaks in the wavelength range of a visible light region (e.g., 350 nm to 750 nm) is preferably employed. Furthermore, an emission spectrum of a material having a peak in a yellow wavelength region preferably has spectral components also in green and red wavelength regions.

The EL layer 115 can have a structure in which a light-emitting layer containing a light-emitting material that emits light of one color and a light-emitting layer containing a light-emitting material that emits light of another color are stacked. For example, the plurality of light-emitting layers in the EL layer 115 may be stacked in contact with each other or may be stacked with a region not including any light-emitting material therebetween. For example, between a fluorescent light-emitting layer and a phosphorescent light-emitting layer, a region that contains the same material as the fluorescent light-emitting layer or the phosphorescent light-emitting layer (for example, a host material or an assist material) and no light-emitting material may be provided. This facilitates the manufacture of the light-emitting element and reduces drive voltage.

In addition, the light-emitting element 120 may be a single element including one EL layer or a tandem element in which a plurality of EL layers are stacked with a charge-generation layer therebetween.

As illustrated in FIG. 4A, the EL layer 115 is provided to be shared by the light-emitting elements 120. In FIG. 4A, a continuous EL layer 115 is provided to cover the conductive layers 111 of the light-emitting elements 120. In addition, as illustrated in FIG. 4A, the conductive layer 116 is provided to be shared by the light-emitting element 120R, the light-emitting element 120G, and the light-emitting element 120B. The conductive layer 116 functions as, for example, an electrode to which a common potential is applied. The common EL layer 115 or the common conductive layer 116 is preferably provided because manufacturing steps for the light-emitting element 120 can be reduced.

In the light-emitting element 120, a conductive layer 114 may be provided between the conductive layer 111 and the EL layer 115. The conductive layer 114 has a function of transmitting visible light.

For the conductive layer 114, the conductive film having a property of transmitting visible light can be used. Alternatively, for the conductive layer 114, a film that is formed by making the conductive film that reflects visible light thin enough to transmit visible light can be used. In addition, with a stacked-layer structure of the conductive film and the conductive film that transmits visible light, conductivity and mechanical strength can be increased.

As illustrated in FIG. 4B, the conductive layer 114 is placed between the conductive layer 111 and the EL layer 115. The conductive layer 114 is positioned over the conductive layer 111. Here, the EL layer 115 is preferably provided to cover end portions of the conductive layer 114.

In addition, as illustrated in FIG. 4B, the thicknesses of the conductive layers 114 included in the light-emitting elements 120 are preferably different between the light-emitting elements. Among the three conductive layers 114, the conductive layer 114B has the smallest thickness, and the conductive layer 114R has the largest thickness. Here, as to a distance between the top surface of the conductive layer 111 and a lower surface of the conductive layer 116 in each light-emitting element (i.e., an interface between the conductive layer 116 and the EL layer 115), the light-emitting element 120R has the largest distance, and the light-emitting element 120B has the smallest distance. When the distance between the top surface of the conductive layer 111 and the lower surface of the conductive layer 116 in each light-emitting element is changed, an optical distance (optical path length) in each light-emitting element can be changed.

The light-emitting element 120R has the longest optical path length among the three light-emitting elements, and thus emits light R that is intensified light with the longest wavelength. In contrast, the light-emitting element 120B has the shortest optical path length, and thus emits light B that is intensified light with the shortest wavelength. The light-emitting element 120G emits light G that is intensified light with an intermediate wavelength. For example, the light R is intensified red light, the light G is intensified green light, and the light B is intensified blue light.

With such a structure, it is not necessary to form the EL layers included in the light-emitting elements 120 separately for light-emitting elements with different colors; thus, color display with high color reproducibility can be performed using elements with the same structure. In addition, the light-emitting elements 120 can be placed with extremely high density. For example, a display device having definition exceeding 5000 ppi can be achieved.

In each of the light-emitting elements, the optical distance between the surface of the conductive layer 111 that reflects visible light and the conductive layer 116 having a semi-transmissive property and a semi-reflective property with respect to visible light is preferably adjusted to be mλ/2 (m is a natural number and m is not 0) or in the vicinity thereof with respect to a wavelength λ of light whose intensity is to be increased.

Note that to be exact, the optical distance depends on a product of a physical distance between a reflective surface of the conductive layer 111 and a reflective surface of the conductive layer 116 having a semi-transmissive property and a semi-reflective property and a refractive index of a layer provided therebetween, and thus is difficult to adjust the optical distance precisely. Thus, it is preferable to adjust the optical distance on the assumption that the surface of the conductive layer 111 and the surface of the conductive layer 116 having a semi-transmissive property and a semi-reflective property are the reflective surfaces.

In addition, when a coloring layer that is overlapped with the light-emitting element 120 is provided as described later, the color purity of light from the light-emitting element can be increased.

Note that the light-emitting element 120 may have a stacked-layer structure of a plurality of EL layers. For example, the EL layer 115 may have a stacked-layer structure of the EL layer 115B containing a light-emitting substance that emits blue light, the EL layer 115G containing a light-emitting substance that emits green light, and the EL layer 115R containing a light-emitting substance that emits red light. Each EL layer may include an electron-injection layer, an electron-transport layer, a charge-generation layer, a hole-transport layer, a hole-injection layer, and the like in addition to a layer containing a light-emitting compound. Note that a charge-generation layer may be provided between the EL layer 115B and the EL layer 115G. In addition, a charge-generation layer may be provided between the EL layer 115G and the EL layer 115R.

### <EL Layer Structure Example>

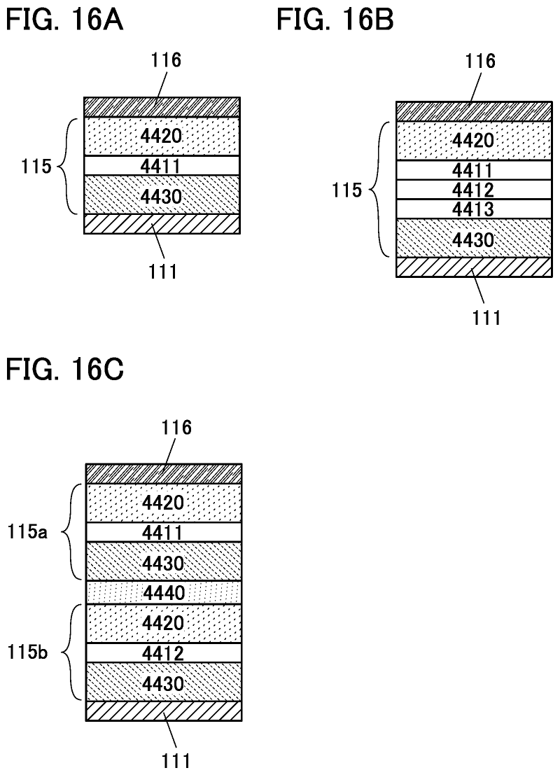

The EL layer 115 included in the light-emitting element 120 can be formed of a plurality of layers such as a layer 4420, a light-emitting layer 4411, and a layer 4430, as illustrated in FIG. 16A. The layer 4420 can include, for example, a layer containing a substance with a high electron-injection property (an electron-injection layer), a layer containing a substance with a high electron-transport property (an electron-transport layer), and the like. The light-emitting layer 4411 contains a light-emitting compound, for example. The layer 4430 can include, for example, a layer containing a substance with a high hole-injection property (a hole-injection layer), a layer containing a substance with a high hole-transport property (a hole-transport layer), and the like.

The structure including the layer 4420, the light-emitting layer 4411, and the layer 4430 that is provided between a pair of electrodes can function as a single light-emitting unit, and the structure in FIG. 16A is referred to as a single structure in this specification.

Note that a structure in which a plurality of light-emitting layers (light-emitting layers 4411, 4412, and 4413) are provided between the layer 4420 and the layer 4430 as illustrated in FIG. 16B is also a variation of the single structure.

In addition, a structure in which a plurality of light-emitting units (EL layers 115a and 115b) are connected in series with an intermediate layer (charge-generation layer) 4440 therebetween as illustrated in FIG. 16C is referred to as a tandem structure in this specification. Note that in this specification and the like, the structure illustrated in FIG. 16C is referred to as a tandem structure; however, without being limited to this, a tandem structure may be referred to as a stack structure, for example. Note that the tandem structure enables a light-emitting element capable of light emission at high luminance.

The light emission color of the light-emitting element can be red, green, blue, cyan, magenta, yellow, white, or the like depending on the material that constitutes the EL layer 115. Furthermore, the color purity can be further increased when the light-emitting element has a microcavity structure.

The light-emitting element that emits white light preferably contains two or more kinds of light-emitting substances in the light-emitting layer. To obtain white light emission, two or more light-emitting substances are selected such that their light emission colors are complementary colors.

The light-emitting layer preferably contains two or more light-emitting substances that emit red (R) light, green (G) light, blue (B) light, yellow (Y) light, orange (O) light, and the like. Alternatively, it is preferable that the light-emitting layer contain two or more light-emitting substances and that the light emission of each light-emitting substance contain spectral components of two or more colors of R, G, and B.

### Manufacturing Method Example

An example of a method for manufacturing the display device according to one embodiment of the present invention will be described with reference to drawings.

Note that thin films that constitute the display device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD: Plasma Enhanced CVD) method, a thermal CVD method, and the like. In addition, as an example of the thermal CVD method, a metal organic chemical vapor deposition (MOCVD: Metal Organic CVD) method can be given.

Alternatively, thin films that constitute the display device (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

Furthermore, when the thin films that constitute the display device are processed, a photolithography method or the like can be used for the processing. Besides, a nanoimprinting method, a sandblasting method, a lift-off method, or the like may be used for the processing of the thin films. Alternatively, island-shaped thin films may be directly formed by a deposition method using a blocking mask such as a metal mask.

There are the following two typical ways of a photolithography method. One is a method in which a resist mask is formed over a thin film that is to be processed, the thin film is processed by etching or the like, and the resist mask is removed. The other is a method in which, after a photosensitive thin film is deposited, light exposure and development are performed, and the thin film is processed into a desired shape.

As light used for light exposure in the photolithography method, for example, an i-line (with a wavelength of 365 nm), a g-line (with a wavelength of 436 nm), an h-line (with a wavelength of 405 nm), or combined light of them can be used. Besides, ultraviolet light, KrF laser light, ArF laser light, or the like can be used. In addition, the light exposure may be performed by liquid immersion light exposure technique. Alternatively, as the light used for the light exposure, extreme ultra-violet (EUV) light, X-rays, or the like may be used. Furthermore, instead of the light used for the light exposure, an electron beam can also be used. It is preferable to use extreme ultraviolet light, X-rays, or an electron beam because extremely minute processing can be performed. Note that a photomask is not necessarily required when light exposure is performed by scanning of a beam such as an electron beam.

For etching of the thin film, a dry etching method, a wet etching method, a sandblasting method, or the like can be used.

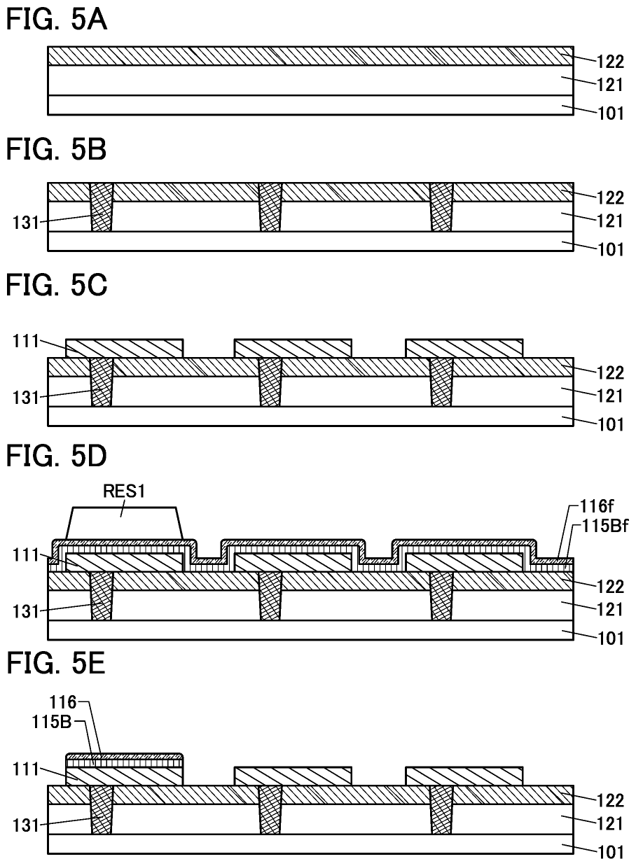

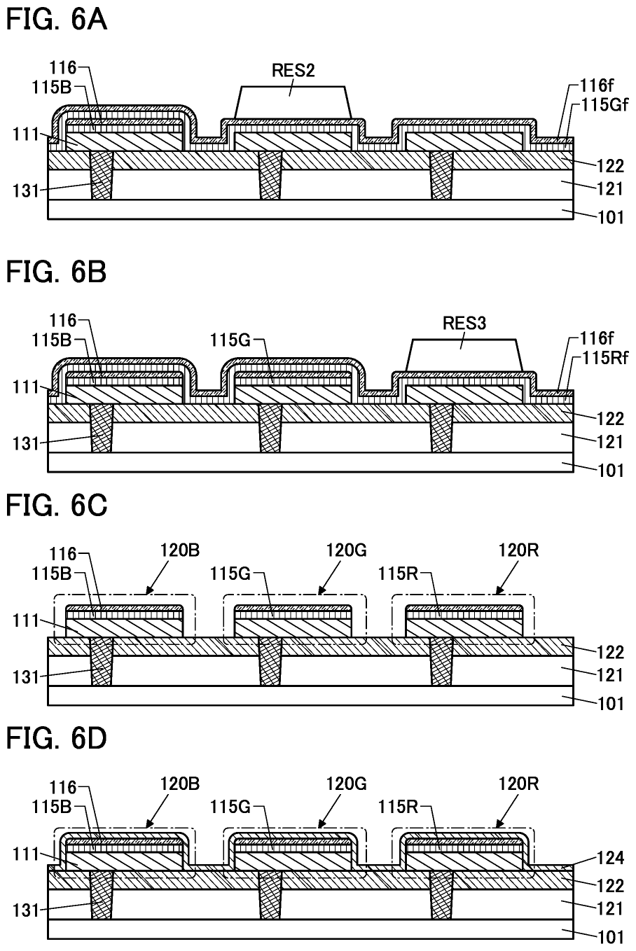

Examples of a method for manufacturing the display device illustrated in FIG. 1B will be described using FIGS. 5A to 5E and FIGS. 6A to 6D. The use of the manufacturing method illustrated in FIG. 5A to FIG. 5E and FIG. 6A to FIG. 6D enables processing of the EL layer 115 and the conductive layer 116 without the use of a metal mask.

### [Preparation for Substrate 101]

As the substrate 101, a substrate having at least heat resistance high enough to withstand the following heat treatment can be used. In the case where an insulating substrate is used as the substrate 101, a glass substrate, a quartz substrate, a sapphire substrate, a ceramic substrate, or the like can be given. Alternatively, it is possible to use a semiconductor substrate such as a single crystal semiconductor substrate or a polycrystalline semiconductor substrate including silicon, silicon carbide, or the like as a material; a compound semiconductor substrate of silicon germanium or the like; or an SOI substrate.

As the substrate 101, it is particularly preferable to use the semiconductor substrate or the insulating substrate over which a semiconductor circuit including a semiconductor element such as a transistor is formed. Such a semiconductor element may be formed using a semiconductor substrate such as a single crystal silicon substrate or may be formed using an oxide semiconductor film. The semiconductor circuit preferably constitutes a pixel circuit, a gate line driver circuit (a gate driver), a source line driver circuit (a source driver), or the like. In addition to the above, an arithmetic circuit, a memory circuit, or the like may be formed.

In this embodiment, a substrate including at least a pixel circuit is used as the substrate 101.

### [Deposition of Insulating Layer 121 and Insulating Layer 122]

An insulating film to be the insulating layer 121 is deposited over the substrate 101. Next, an insulating film to be the insulating layer 122 is deposited over the insulating layer 121 (see FIG. 5A). The insulating layer 121 and the insulating layer 122 can be formed using the insulating material and the deposition method as appropriate.

Here, by using a material with a low etching rate for the insulating layer 122, the insulating layer 122 can function as an etching stopper when the conductive layer 111, the EL layer 115, and the conductive layer 116 are formed.

Note that as illustrated in FIG. 1C, it is also possible to employ a structure where the insulating layer 122 is not provided. In that case, a material with a high etching rate can be used for the insulating layer 121. Thus, an opening in which the plug 131 is embedded can be formed comparatively easily in a later step. In addition, a concave portion is sometimes formed in a region of the insulating layer 121 that is not overlapped with the conductive layer 111, for example, in a step of forming the conductive layer 111 to be described later.

### [Formation of Plug 131]

Next, an opening reaching the substrate 101 is formed in the insulating layer 121 and the insulating layer 122 in a position where the plug 131 is to be formed. The opening is preferably an opening reaching an electrode or a wiring provided in the substrate 101. Next, a conductive film is formed to fill the opening and then planarization treatment is performed to expose the top surface of the insulating layer 122. Accordingly, the plug 131 embedded in the insulating layer 121 and the insulating layer 122 can be formed (see FIG. 5B).

### [Formation of Conductive Layer 111]

A conductive film is deposited over the insulating layer 122 and the plug 131. The conductive film is processed into an island shape so that the conductive layer 111 is formed (see FIG. 5C). The conductive layer 111 is electrically connected to the plug 131.

### [Formation of EL Layer 115 and Conductive Layer 116]

Next, an EL layer 1151Bf and a conductive layer 116f of the light-emitting element 120B are sequentially deposited over the conductive layer 111 and the insulating layer 122. Next, a pattern using a resist RES1 is formed over the conductive layer 116f (see FIG. 5D). Here, the EL layer 115Bf is a layer to be the EL layer 115B in a later step. In addition, the conductive layer 116f is a layer to be the conductive layer 116 in a later step. Furthermore, the EL layer 115Bf, and an EL layer 115Gf and an EL layer 115Rf to be described later are sometimes collectively referred to as an EL layer 115f.

The EL layer 115f includes at least a layer containing a light-emitting compound. Besides, a structure may be employed in which an electron-injection layer, an electron-transport layer, a charge-generation layer, a hole-transport layer, and a hole-injection layer are stacked. The EL layer 115f can be formed by, for example, a liquid phase method such as an evaporation method or an inkjet method.

The conductive layer 116f is formed to have a property of transmitting and reflecting visible light. For example, a metal film or an alloy film that is thin enough to transmit visible light can be used. Alternatively, a light-transmitting conductive film (e.g., a metal oxide film) may be stacked over such a film.

Next, etching is performed using the resist RES1 as a mask so that the conductive layer 116 and the EL layer 115B are sequentially formed, and then the resist RES1 is removed (see FIG. 5E).

Next, the EL layer 115Gf and the conductive layer 116f of the light-emitting element 120G are sequentially deposited over the conductive layer 111, the insulating layer 122, and the conductive layer 116 of the light-emitting element 120B. Next, a pattern using a resist RES2 is formed over the conductive layer 116f (see FIG. 6A). Here, the EL layer 115Gf is a layer to be the EL layer 115G in a later step.

Next, etching is performed using the resist RES2 as a mask so that the conductive layer 116 and the EL layer 115G are sequentially formed, and then the resist RES2 is removed.

Next, the EL layer 115Rf and the conductive layer 116f of the light-emitting element 120R are sequentially deposited over the conductive layer 111, the insulating layer 122, the conductive layer 116 of the light-emitting element 120B, and the conductive layer 116 of the light-emitting element 120G. Next, a pattern using a resist RES3 is formed over the conductive layer 116f (see FIG. 6B). Here, the EL layer 115Rf is a layer to be the EL layer 115R in a later step.

Next, etching is performed using the resist RES3 as a mask so that the conductive layer 116 and the EL layer 115R are sequentially formed, and then the resist RES3 is removed (see FIG. 6C).

Note that in this embodiment, the EL layer 115 and the conductive layer 116 are formed after the conductive layer 111 is formed; however, the present invention is not limited thereto. For example, the conductive layer 111, the EL layer 115, and the conductive layer 116 can also be formed by sequentially depositing a layer to be the conductive layer 111, the EL layer 115f, and the conductive layer 116f and processing the layer to be the conductive layer 111, the EL layer 115f, and the conductive layer 116f into an island shape at a time.

### [Deposition of Insulating Layer 124]

Next, an insulating film to be the insulating layer 124 is deposited over the insulating layer 122 and the conductive layer 116 (see FIG. 6D). The insulating layer 124 can be formed using the insulating material and the deposition method as appropriate. Note that the deposition temperature of the insulating layer 124 is preferably within a range where the EL layer 115 does not deteriorate. Alternatively, as illustrated in FIG. 1A, it is also possible to employ a structure where the insulating layer 124 is not provided.

Accordingly, it is possible to form the display device 100 that includes the light-emitting element 120R, the light-emitting element 120G, and the light-emitting element 120B.

### Structure Example 2

An example of a display device including transistors will be described below.

### Structure Example 2-1

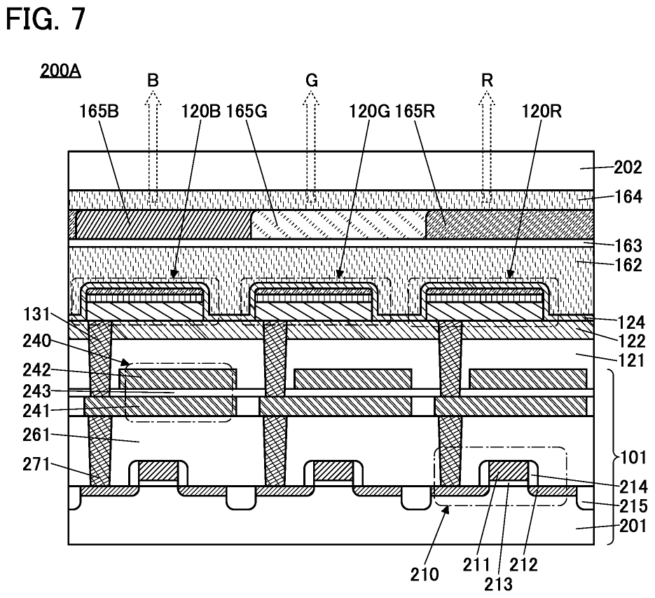

FIG. 7 is a schematic cross-sectional view of a display device 200A.

The display device 200A includes a substrate 201, the light-emitting element 120R, the light-emitting element 120G, the light-emitting element 120B, a capacitor 240, transistors 210, and the like.

A stack structure from the substrate 201 to the capacitor 240 corresponds to the substrate 101 in Structure Example 1.

The transistor 210 is a transistor whose channel formation region is formed in the substrate 201. As the substrate 201, a semiconductor substrate such as a single crystal silicon substrate can be used, for example. The transistor 210 includes part of the substrate 201, a conductive layer 211, a low-resistance region 212, an insulating layer 213, an insulating layer 214, and the like. The conductive layer 211 functions as a gate electrode. The insulating layer 213 is positioned between the substrate 201 and the conductive layer 211 and functions as a gate insulating layer. The low-resistance region 212 is a region where the substrate 201 is doped with an impurity, and functions as one of a source and a drain. The insulating layer 214 is provided to cover a side surface of the conductive layer 211 and functions as a sidewall insulating layer.

In addition, an element isolation layer 215 is provided between two adjacent transistors 210 to be embedded in the substrate 201.

Furthermore, an insulating layer 261 is provided to cover the transistors 210, and the capacitor 240 is provided over the insulating layer 261.

The capacitor 240 includes a conductive layer 241, a conductive layer 242, and an insulating layer 243 positioned therebetween. The conductive layer 241 functions as one electrode of the capacitor 240. The conductive layer 242 functions as the other electrode of the capacitor 240. The insulating layer 243 functions as a dielectric of the capacitor 240.

The conductive layer 241 is provided over the insulating layer 261 and is electrically connected to one of a source and a drain of the transistor 210 through a plug 271 embedded in the insulating layer 261. The insulating layer 243 is provided to cover the conductive layer 241. The conductive layer 242 is provided in a region that is overlapped with the conductive layer 241 with the insulating layer 243 therebetween.

The insulating layer 121 is provided to cover the capacitor 240. The insulating layer 122 is provided over the insulating layer 121. The light-emitting element 120R, the light-emitting element 120G, the light-emitting element 120B, and the like are provided. Here, an example where the structure illustrated in FIG. 1B is used as the structure of the light-emitting element 120R, the light-emitting element 120G, the light-emitting element 120B, or the like; however, the structure is not limited thereto and a variety of structures illustrated above can be employed.

In the display device 200A, the insulating layer 124, an insulating layer 162, and an insulating layer 163 are provided in that order to cover the conductive layer 116 of the light-emitting element 120. These three insulating layers each function as a protective layer that prevents diffusion of impurities such as water into the light-emitting element 120. For the insulating layer 163, it is preferable to use an inorganic insulating film with low moisture permeability, such as a silicon oxide film, a silicon nitride film, or an aluminum oxide film. In addition, for the insulating layer 162, an organic insulating film having a high light-transmitting property can be used. Using an organic insulating film for the insulating layer 162 can ease the impact of an uneven shape below the insulating layer 162, so that the formation surface of the insulating layer 163 can be a smooth surface. Accordingly, a defect such as a pinhole is less likely to be generated in the insulating layer 163, which leads to higher moisture permeability of the protective layer. Note that the structure of the protective layer covering the light-emitting element 120 is not limited thereto, and a single layer or a two-layer structure may be employed or a stacked-layer structure of four or more layers may be employed.

Providing the insulating layer 122 or the insulating layer 124 inhibits diffusion of impurities such as water or hydrogen into the light-emitting element 120, as described in the above embodiment.

A coloring layer 165R that is overlapped with the light-emitting element 120R, a coloring layer 165G that is overlapped with the light-emitting element 120G, and a coloring layer 165B that is overlapped with the light-emitting element 120B are provided over the insulating layer 163. For example, the coloring layer 165R transmits red light, the coloring layer 165G transmits green light, and the coloring layer 165B transmits blue light. This can increase the color purity of light from the light-emitting elements, so that a display device with higher display quality can be achieved. Furthermore, forming the coloring layers over the insulating layer 163 makes it easier to align light-emitting units and the coloring layers than the case where the coloring layers are formed over a substrate 202 to be described later, so that a display device with extremely high definition can be achieved. Note that a structure may be employed in which none of the coloring layer 165R, the coloring layer 165G, and the coloring layer 165B is provided.

The display device 200A includes the substrate 202 on the viewing side. The substrate 202 and the substrate 201 are bonded to each other with a light-transmitting adhesive layer 164. As the substrate 202, a light-transmitting substrate, such as a glass substrate, a quartz substrate, a sapphire substrate, or a plastic substrate, can be used.

With such a structure, a display device with extremely high definition and high display quality can be achieved.

### Structure Example 2-2

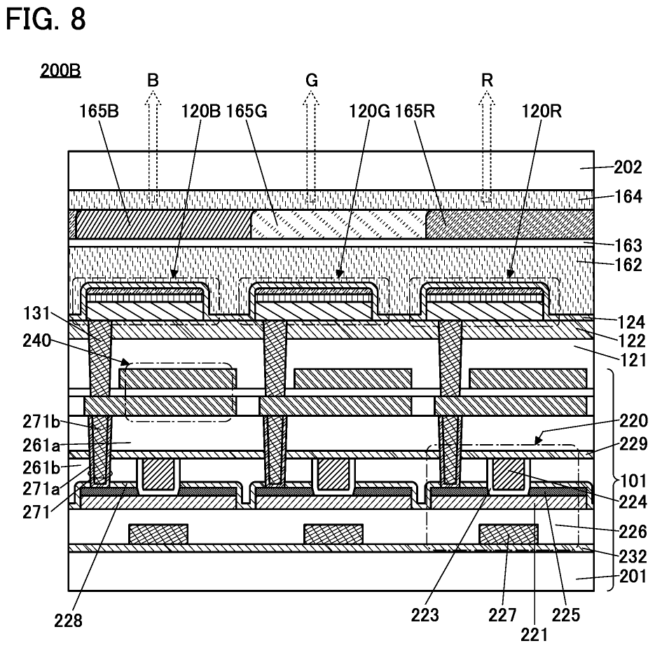

FIG. 8 is a schematic cross-sectional view of a display device 200B. The display device 200B differs from the display device 200A mainly in a transistor structure.

A transistor 220 is a transistor in which a metal oxide (also referred to as an oxide semiconductor) is used in a semiconductor layer where a channel is formed.

The transistor 220 includes a semiconductor layer 221, an insulating layer 223, a conductive layer 224, a pair of conductive layers 225, an insulating layer 226, a conductive layer 227, and the like.

As the substrate 201 over which the transistor 220 is provided, the above insulating substrate or semiconductor substrate can be used.

An insulating layer 232 is provided over the substrate 201. The insulating layer 232 functions as a barrier layer that prevents diffusion of impurities such as water or hydrogen from the substrate 201 into the transistor 220 and release of oxygen from the semiconductor layer 221 to the insulating layer 232 side. For the insulating layer 232, a film in which hydrogen or oxygen is less likely to be diffused than in a silicon oxide film such as an aluminum oxide film, a hafnium oxide film, or a silicon nitride film can be used, for example.

The conductive layer 227 is provided over the insulating layer 232, and the insulating layer 226 is provided to cover the conductive layer 227. The conductive layer 227 functions as a first gate electrode of the transistor 220, and part of the insulating layer 226 functions as a first gate insulating layer. For the insulating layer 226 at least in a portion in contact with the semiconductor layer 221, an oxide insulating film such as a silicon oxide film is preferably used. In addition, a top surface of the insulating layer 226 is preferably planarized.

The semiconductor layer 221 is provided over the insulating layer 226. The semiconductor layer 221 preferably includes a film of a metal oxide having semiconductor characteristics (also referred to as an oxide semiconductor). The material that can be suitably used for the semiconductor layer 221 is described in detail later.

The pair of conductive layers 225 is provided on and in contact with the semiconductor layer 221, and functions as a source electrode and a drain electrode.

In addition, an insulating layer 228 is provided to cover top surfaces and side surfaces of the pair of conductive layers 225, side surfaces of the semiconductor layer 221, and the like, and an insulating layer 261b is provided over the insulating layer 228. The insulating layer 228 functions as a barrier layer that prevents diffusion of impurities such as water or hydrogen from the insulating layer 261b or the like into the semiconductor layer 221 and release of oxygen from the semiconductor layer 221. For the insulating layer 228, an insulating film similar to the insulating layer 232 can be used.

An opening reaching the semiconductor layer 221 is provided in the insulating layer 228 and the insulating layer 261b. The insulating layer 223 that is in contact with the side surfaces of the insulating layer 261b, the insulating layer 228, and the conductive layer 225 and the top surface of the semiconductor layer 221, and the conductive layer 224 are embedded in the opening. The conductive layer 224 functions as a second gate electrode, and the insulating layer 223 functions as a second gate insulating layer.

The top surface of the conductive layer 224, the top surface of the insulating layer 223, and the top surface of the insulating layer 261b are subjected to planarization treatment so that they are substantially level with each other, and an insulating layer 229 and an insulating layer 261a are provided to cover these layers.

The insulating layer 261a and the insulating layer 261b function as an interlayer insulating layer. In addition, the insulating layer 229 functions as a barrier layer that prevents diffusion of impurities such as water or hydrogen from the insulating layer 261a or the like to the transistor 220. As the insulating layer 229, an insulating film similar to the insulating layer 228 and the insulating layer 232 can be used.

The plug 271 electrically connected to one of the pair of conductive layers 225 is provided to be embedded in the insulating layer 261a, the insulating layer 229, and the insulating layer 261b. Here, the plug 271 preferably includes a conductive layer 271a covering side surfaces of the opening in the insulating layer 261a, the insulating layer 261b, the insulating layer 229, and the insulating layer 228, and part of a top surface of the conductive layer 225, and a conductive layer 271b in contact with a top surface of the conductive layer 271a. In this case, a conductive material in which hydrogen and oxygen are less likely to be diffused is preferably used for the conductive layer 271a.

In addition, providing the insulating layer 122 or the insulating layer 124 inhibits diffusion of impurities such as water or hydrogen into the transistor 220, as described in later embodiments. Thus, the electrical characteristics and reliability of the transistor 220 can be improved.

### Structure Example 2-3

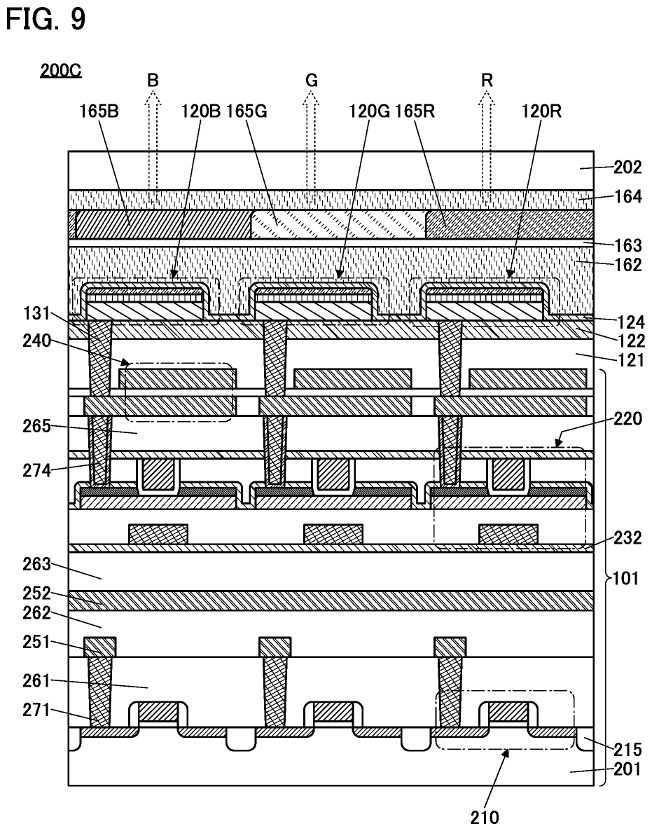

FIG. 9 is a schematic cross-sectional view of a display device 200C. The display device 200C has a structure in which the transistor 210 whose channel is formed in the substrate 201 and the transistor 220 including a metal oxide in the semiconductor layer where the channel is formed are stacked.

The insulating layer 261 is provided to cover the transistor 210, and a conductive layer 251 is provided over the insulating layer 261. In addition, an insulating layer 262 is provided to cover the conductive layer 251, and a conductive layer 252 is provided over the insulating layer 262. The conductive layer 251 and the conductive layer 252 each function as a wiring. In addition, an insulating layer 263 and the insulating layer 232 are provided to cover the conductive layer 252, and the transistor 220 is provided over the insulating layer 232. Furthermore, an insulating layer 265 is provided to cover the transistor 220, and the capacitor 240 is provided over the insulating layer 265. The capacitor 240 and the transistor 220 are electrically connected to each other through a plug 274.

The transistor 220 can be used as a transistor included in a pixel circuit. In addition, the transistor 210 can be used as a transistor included in a pixel circuit or a transistor included in a driver circuit (a gate line driver circuit or a source line driver circuit) for driving the pixel circuit. Furthermore, the transistor 210 and the transistor 220 can be used as transistors included in a variety of circuits such as an arithmetic circuit or a memory circuit.

With such a structure, not only the pixel circuit but also the driver circuit or the like can be formed directly under the light-emitting unit; thus, the display device can be downsized as compared with the case where the driver circuit is provided around a display region.

### Structure Example 2-4

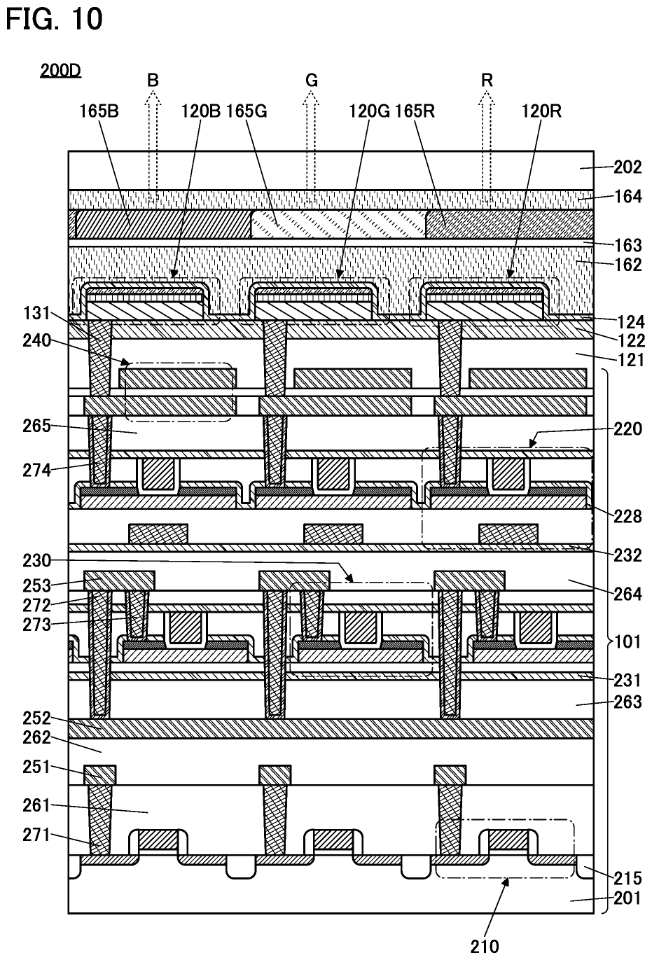

FIG. 10 is a schematic cross-sectional view of a display device 200D. The display device 200D differs from the display device 200C mainly in that two transistors where an oxide semiconductor is employed are stacked.

The display device 200D includes a transistor 230 between the transistor 210 and the transistor 220. The transistor 230 has a structure similar to that of the transistor 220 except that the first gate electrode is not included. Note that the transistor 230 may have a structure including the first gate electrode.

The insulating layer 263 and an insulating layer 231 are provided to cover the conductive layer 252, and the transistor 230 is provided over the insulating layer 231. The transistor 230 and the conductive layer 252 are electrically connected to each other through a plug 273, a conductive layer 253, and a plug 272. In addition, an insulating layer 264 and the insulating layer 232 are provided to cover the conductive layer 253, and the transistor 220 is provided over the insulating layer 232.

For example, the transistor 220 functions as a transistor for controlling current flowing through the light-emitting element 120. In addition, the transistor 230 functions as a selection transistor for controlling the selection state of a pixel. Furthermore, the transistor 210 functions as a transistor included in a driver circuit for driving the pixel, for example.

When three or more layers in which a transistor is formed are stacked in this manner, the area occupied by the pixel can be further reduced and a high-definition display device can be achieved.

Components such as a transistor that can be employed in the display device will be described below.

### [Transistor]

The transistors each include a conductive layer functioning as a gate electrode, a semiconductor layer, a conductive layer functioning as a source electrode, a conductive layer functioning as a drain electrode, and an insulating layer functioning as a gate insulating layer.

Note that there is no particular limitation on the structure of the transistor included in the display device according to one embodiment of the present invention. For example, a planar transistor, a staggered transistor, or an inverted staggered transistor may be used. In addition, a top-gate or bottom-gate transistor structure may be employed. Alternatively, gate electrodes may be provided above and below a channel.

There is no particular limitation on the crystallinity of a semiconductor material used for the transistors, and any of an amorphous semiconductor and a crystalline semiconductor (a microcrystalline semiconductor, a polycrystalline semiconductor, a single-crystal semiconductor, or a semiconductor partly including crystal regions) may be used. It is preferable that a crystalline semiconductor be used because degradation of the transistor characteristics can be suppressed.

In particular, a transistor that uses a metal oxide film for a semiconductor layer where a channel is formed will be described below.

As a semiconductor material used for the transistors, a metal oxide whose energy gap is greater than or equal to 2 eV, preferably greater than or equal to 2.5 eV, further preferably greater than or equal to 3 eV can be used. A typical example is a metal oxide containing indium, and a CAC-OS described later can be used, for example.

A transistor in which a metal oxide having a wider band gap and a lower carrier density than silicon is used has low off-state current; thus, charge accumulated in a capacitor that is connected in series with the transistor can be retained for a long period.

The semiconductor layer can be, for example, a film represented by an In-M-Zn-based oxide that contains indium, zinc, and M (M is a metal such as aluminum, titanium, gallium, germanium, yttrium, zirconium, lanthanum, cerium, tin, neodymium, or hafnium).

In the case where the metal oxide contained in the semiconductor layer is an In-M-Zn-based oxide, it is preferable that the atomic ratio of metal elements in a sputtering target used for depositing the In-M-Zn-based oxide satisfy In≥M and Zn≥M. The atomic ratio of metal elements in such a sputtering target is preferably, for example, In:M:Zn=1:1:1, In:M:Zn=1:1:1.2, In:M:Zn=3:1:2, In:M:Zn=4:2:3, In:M:Zn=4:2:4.1, In:Zn=5:1:6, In:M:Zn=5:1:7, In:M:Zn=5:1:8, or the like. Note that the atomic ratio in the deposited semiconductor layer varies from the atomic ratio of metal elements of the sputtering target in a range of ±40%.

A metal oxide film with a low carrier density is used as the semiconductor layer. For example, for the semiconductor layer, a metal oxide whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³ can be used. Such a metal oxide is referred to as a highly purified intrinsic or substantially highly purified intrinsic metal oxide. The metal oxide has a low density of defect states and thus can be regarded as a metal oxide having stable characteristics.

Note that, without limitation to those described above, an oxide semiconductor with an appropriate composition may be used in accordance with required semiconductor characteristics and electrical characteristics (field-effect mobility, threshold voltage, and the like) of the transistor. In addition, to obtain the required semiconductor characteristics of the transistor, it is preferable that the carrier density, the impurity concentration, the density of defect states, the atomic ratio between a metal element and oxygen, the interatomic distance, the density, and the like of the semiconductor layer be set to appropriate values.

When silicon or carbon, which is one of Group 14 elements, is contained in the metal oxide contained in the semiconductor layer, oxygen vacancies are increased in the semiconductor layer, and the semiconductor layer becomes n-type. Thus, the concentration of silicon or carbon (concentration obtained by secondary ion mass spectrometry) in the semiconductor layer is set to lower than or equal to 2×10¹⁸ atoms/cm³, preferably lower than or equal to 2×10¹⁷ atoms/cm³.

In addition, alkali metal and alkaline earth metal might generate carriers when bonded to a metal oxide, in which case the off-state current of the transistor might be increased. Thus, the concentration of alkali metal or alkaline earth metal in the semiconductor layer that is obtained by secondary ion mass spectrometry is set to lower than or equal to 1×10¹⁸ atoms/cm³, preferably lower than or equal to 2×10¹⁶ atoms/cm³.

In addition, when nitrogen is contained in the metal oxide contained in the semiconductor layer, electrons serving as carriers are generated and the carrier density increases, so that the semiconductor layer easily becomes n-type. As a result, a transistor using a metal oxide that contains nitrogen is likely to have normally-on characteristics. Accordingly, the nitrogen concentration in the semiconductor layer that is obtained by secondary ion mass spectrometry is preferably set to lower than or equal to 5×10¹⁸ atoms/cm³.

In addition, hydrogen contained in the oxide semiconductor reacts with oxygen bonded to a metal atom to be water, and thus sometimes forms an oxygen vacancy. Entry of hydrogen into the oxygen vacancy generates an electron serving as a carrier in some cases. In other cases, bonding of part of hydrogen to oxygen bonded to a metal atom generates an electron serving as a carrier. Thus, a transistor using an oxide semiconductor that contains hydrogen is likely to have normally-on characteristics. Therefore, hydrogen in a channel formation region of the oxide semiconductor is preferably reduced as much as possible. Specifically, the hydrogen concentration in the channel formation region of the oxide semiconductor that is obtained by secondary ion mass spectrometry is set to lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When an oxide semiconductor with a sufficiently low concentration of impurities is used for a channel formation region of a transistor, the transistor can have stable electrical characteristics and reliability.

In addition, oxide semiconductors can be classified into a single crystal oxide semiconductor and a non-single-crystal oxide semiconductor. Examples of the non-single-crystal oxide semiconductors include a CAAC-OS (c-axis-aligned crystalline oxide semiconductor), a polycrystalline oxide semiconductor, an nc-OS (nanocrystalline oxide semiconductor), an amorphous-like oxide semiconductor (a-like OS), an amorphous oxide semiconductor, and the like.

In addition, a CAC-OS (cloud-aligned composite oxide semiconductor) may be used for a semiconductor layer of a transistor disclosed in one embodiment of the present invention.

Note that the non-single-crystal oxide semiconductor can be suitably used for a semiconductor layer of a transistor disclosed in one embodiment of the present invention. In addition, as the non-single-crystal oxide semiconductor, the nc-OS or the CAAC-OS can be suitably used.

Note that in one embodiment of the present invention, a CAC-OS is preferably used for a semiconductor layer of a transistor. The use of the CAC-OS allows the transistor to have high electrical characteristics or high reliability.

Note that the semiconductor layer may be a mixed film including two or more kinds of a region of a CAAC-OS, a region of a polycrystalline oxide semiconductor, a region of an nc-OS, a region of an amorphous-like oxide semiconductor, and a region of an amorphous oxide semiconductor. The mixed film has, for example, a single-layer structure or a stacked-layer structure including two or more kinds of the above regions in some cases.

### <Composition of CAC-OS>

The composition of a CAC-OS that can be used in a transistor disclosed in one embodiment of the present invention will be described below.

The CAC-OS is, for example, a composition of a material in which elements that constitute a metal oxide are unevenly distributed to have a size of greater than or equal to 0.5 nm and less than or equal to 10 nm, preferably greater than or equal to 1 nm and less than or equal to 2 nm, or a similar size. Note that in the following description, a state in which one or more metal elements are unevenly distributed and regions including the metal element(s) are mixed to have a size of greater than or equal to 0.5 nm and less than or equal to 10 nm, preferably greater than or equal to 1 nm and less than or equal to 2 nm, or a similar size in a metal oxide is referred to as a mosaic pattern or a patch-like pattern.

Note that the metal oxide preferably contains at least indium. In particular, indium and zinc are preferably contained. Moreover, in addition to these, one kind or a plurality of kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For example, a CAC-OS in an In-Ga—Zn oxide (an In-Ga—Zn oxide in the CAC-OS may be particularly referred to as CAC-IGZO) has a composition in which materials are separated into indium oxide (hereinafter referred to as InO_{X1} (X1 is a real number greater than 0)) or indium zinc oxide (hereinafter referred to as In_{X2}Zn_{Y1}O_{Z2} (each of X2, Y2, and Z2 is a real number greater than 0)) and gallium oxide (hereinafter referred to as GaO_{X3} (X3 is a real number greater than 0)), gallium zinc oxide (hereinafter referred to as Ga_{X4}Zn_{Y4}O_{Z4} (each of X4, Y4, and Z4 is a real number greater than 0)), or the like so that a mosaic pattern is formed, and mosaic-like InO_{X1} or In_{X2}Zn_{Y2}O_{Z2} is evenly distributed in the film (this composition is hereinafter also referred to as a cloud-like composition).

That is, the CAC-OS is a composite metal oxide having a composition in which a region where GaO_{X3} is a main component and a region where In_{X2}Zn_{Y1}O_{Z2} or InO_{X1} is a main component are mixed. Note that in this specification, for example, when the atomic ratio of In to an element Min a first region is larger than the atomic ratio of In to the element Min a second region, the first region is regarded as having a higher In concentration than the second region.

Note that IGZO is a commonly known name and sometimes refers to one compound formed of In, Ga, Zn, and O. A typical example is a crystalline compound represented by InGaO₃(ZnO)ₘ₁ (m1 is a natural number) or In(₁₊ₓ₀)Ga(₁₋ₓ₀)O₃(ZnO)m₀ (−1≤x0≤1; m0 is a given number).

The crystalline compound has a single crystal structure, a polycrystalline structure, or a CAAC structure. Note that the CAAC structure is a crystal structure in which a plurality of IGZO nanocrystals have c-axis alignment and are connected in an a-b plane without alignment.

Meanwhile, the CAC-OS relates to the material composition of a metal oxide. In the material composition of a CAC-OS containing In, Ga, Zn, and O, some regions that contain Ga as a main component and are observed as nanoparticles and some regions that contain In as a main component and are observed as nanoparticles are each randomly dispersed in a mosaic pattern. Therefore, the crystal structure is a secondary element for the CAC-OS.

Note that the CAC-OS is regarded as not including a stacked-layer structure of two or more kinds of films with different compositions. For example, a two-layer structure of a film containing In as a main component and a film containing Ga as a main component is not included.

Note that a clear boundary between the region where GaO_{X3} is a main component and the region where In_{X2}Zn_{Y2}O_{Z2} or InO_{X1} is a main component cannot be observed in some cases.

Note that in the case where one kind or a plurality of kinds selected from aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium, the CAC-OS refers to a composition in which some regions that contain the metal element(s) as a main component and are observed as nanoparticles and some regions that contain In as a main component and are observed as nanoparticles are each randomly dispersed in a mosaic pattern.

The CAC-OS can be formed by a sputtering method under a condition where a substrate is not heated, for example. In addition, in the case of forming the CAC-OS by a sputtering method, one or more selected from an inert gas (typically, argon), an oxygen gas, and a nitrogen gas may be used as a deposition gas. Furthermore, the ratio of the flow rate of an oxygen gas to the total flow rate of the deposition gas at the time of deposition is preferably as low as possible, and for example, the ratio of the flow rate of the oxygen gas is preferably higher than or equal to 0% and lower than 30%, further preferably higher than or equal to 0% and lower than or equal to 10%.

The CAC-OS is characterized in that no clear peak is observed at the time of measurement using θ/2θ scan by an Out-of-plane method, which is one of the X-ray diffraction (XRD) measurement methods. That is, it is found from X-ray diffraction measurement that no alignment in an a-b plane direction and a c-axis direction is observed in a measured region.

In addition, in an electron diffraction pattern of the CAC-OS that is obtained by irradiation with an electron beam with a probe diameter of 1 nm (also referred to as a nanobeam electron beam), a ring-like region with high luminance and a plurality of bright spots in the ring-like region are observed. It is therefore found from the electron diffraction pattern that the crystal structure of the CAC-OS includes an nc (nano-crystal) structure with no alignment in a plan-view direction and a cross-sectional direction.

Moreover, for example, it can be confirmed by EDX mapping obtained using energy dispersive X-ray spectroscopy (EDX) that the CAC-OS in the In-Ga—Zn oxide has a composition in which regions where GaO_{X3} is a main component and regions where In_{X2}Zn_{Y1}O_{Z2} or InO_{X1} is a main component are unevenly distributed and mixed.

The CAC-OS has a composition different from that of an IGZO compound in which metal elements are evenly distributed, and has characteristics different from those of the IGZO compound. That is, the CAC-OS has a composition in which regions where GaO_{X3} or the like is a main component and regions where In_{X2}Zn_{Y1}O_{Z2} or InO_{X1} is a main component are phase-separated from each other, and the regions including the respective elements as the main components form a mosaic pattern.

Here, a region where In_{X2}Zn_{Y1}O_{Z2} or InO_{X1} is a main component is a region whose conductivity is higher than that of a region where GaO_{X3} or the like is a main component. In other words, when carriers flow through regions where In_{X2}Zn_{Y2}O_{Z2} or InO_{X1} is a main component, the conductivity of a metal oxide is exhibited. Accordingly, when the regions where In_{X2}Zn_{Y1}O_{Z2} or InO_{X1} is a main component are distributed like a cloud in a metal oxide, high field-effect mobility (μ) can be achieved.

In contrast, a region where GaO_{X3} or the like is a main component is a region whose insulating property is higher than that of a region where In_{X2}Zn_{Y1}O_{Z2} or InO_{X1} is a main component. In other words, when regions where GaO_{X3} or the like is a main component are distributed in a metal oxide, leakage current can be suppressed and favorable switching operation can be achieved.

Accordingly, when the CAC-OS is used for a semiconductor element, the insulating property derived from GaO_{X3} or the like and the conductivity derived from In_{X2}Zn_{Y1}O_{Z2} or InO_{X1} complement each other, so that high on-state current (Iₒₙ) and high field-effect mobility (μ) can be achieved.

In addition, a semiconductor element using the CAC-OS has high reliability. Thus, the CAC-OS is suitable for a variety of semiconductor devices typified by a display.

In addition, since a transistor including the CAC-OS in a semiconductor layer has high field-effect mobility and high drive capability, the use of the transistor in a driver circuit, a typical example of which is a scan line driver circuit that generates a gate signal, can provide a display device with a narrow bezel width (also referred to a narrow bezel). Furthermore, with the use of the transistor in a signal line driver circuit that is included in a display device (particularly in a demultiplexer connected to an output terminal of a shift register included in a signal line driver circuit), a display device to which a small number of wirings are connected can be provided.

Furthermore, unlike a transistor including low-temperature polysilicon, the transistor including the CAC-OS in the semiconductor layer does not need a laser crystallization step. Thus, the manufacturing cost of a display device can be reduced even when the display device is formed using a large area substrate. In addition, the transistor including the CAC-OS in the semiconductor layer is preferably used for a driver circuit and a display portion in a large display device having high resolution such as ultra-high definition (“4K resolution,” “4K2K,” and “4K”) or super high definition (“8K resolution,” “8K4K,” and “8K”) because writing can be performed in a short time and display defects can be reduced.

Alternatively, silicon may be used for a semiconductor in which a channel of a transistor is formed. Although amorphous silicon may be used as silicon, silicon having crystallinity is particularly preferably used. For example, microcrystalline silicon, polycrystalline silicon, single crystal silicon, or the like is preferably used. In particular, polycrystalline silicon can be formed at a temperature lower than that for single crystal silicon and has higher field-effect mobility and higher reliability than amorphous silicon.

### [Conductive Layer]

Examples of materials that can be used for conductive layers of a variety of wirings and electrodes and the like included in the display device in addition to a gate, a source, and a drain of a transistor include metals such as aluminum, titanium, chromium, nickel, copper, yttrium, zirconium, molybdenum, silver, tantalum, and tungsten and an alloy containing such a metal as its main component. Alternatively, a single layer or a stacked-layer structure including a film containing these materials can be used. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, a three-layer structure in which an aluminum film or a copper film is stacked over a molybdenum film or a molybdenum nitride film and a molybdenum film or a molybdenum nitride film is formed thereover, and the like can be given. Note that an oxide such as indium oxide, tin oxide, or zinc oxide may be used. In addition, copper containing manganese is preferably used because controllability of a shape by etching is increased.

### [Insulating Layer]

Examples of an insulating material that can be used for each insulating layer include, in addition to a resin such as acrylic resin or an epoxy resin and a resin having a siloxane bond, such as silicone, an inorganic insulating material such as silicon oxide, silicon oxynitride, silicon nitride oxide, silicon nitride, or aluminum oxide.

Note that in this specification, an oxynitride refers to a material that contains more oxygen than nitrogen in its composition, and a nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

In addition, the light-emitting element is preferably provided between a pair of insulating films with low water permeability. In that case, impurities such as water can be inhibited from entering the light-emitting element, and a decrease in the reliability of the device can be inhibited.

Examples of the insulating film with low water permeability include a film containing nitrogen and silicon, such as a silicon nitride film and a silicon nitride oxide film, and a film containing nitrogen and aluminum, such as an aluminum nitride film. Alternatively, a silicon oxide film, a silicon oxynitride film, an aluminum oxide film, or the like may be used.

For example, the moisture vapor transmission rate of the insulating film with low water permeability is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], still further preferably lower than or equal to 1×10⁻¹ [g/(m²·day)].

### [Structure Example of Display Module]

A structure example of a display module including the display device according to one embodiment of the present invention will be described below.

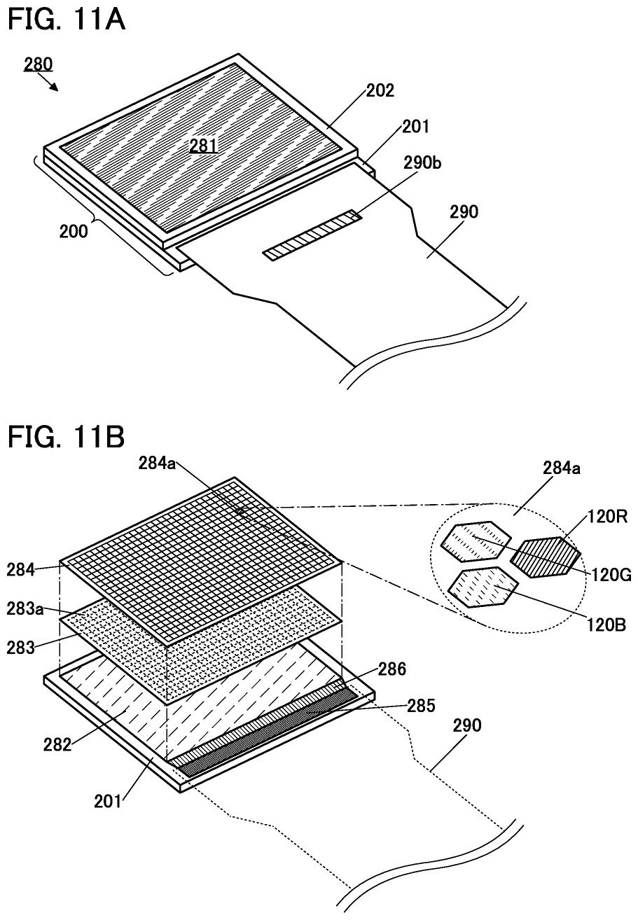

FIG. 11A is a schematic perspective view of a display module 280. The display module 280 includes a display device 200 and an FPC 290. The display devices (the display device 200A to the display device 200D) described in Structure Example 2 can be applied to the display device 200.

The display module 280 includes the substrate 201 and the substrate 202. A display portion 281 is also included on the substrate 202 side. The display portion 281 is a region of the display module 280 where an image is displayed and is a region where light emitted from pixels provided in a pixel portion 284 described later can be seen. In addition, the display module 280 may include a source driver IC 290b.

FIG. 11B illustrates a perspective view schematically illustrating a structure on the substrate 201 side. The substrate 201 has a structure in which a circuit portion 282, a pixel circuit portion 283 over the circuit portion 282, and the pixel portion 284 over the pixel circuit portion 283 are stacked. In addition, a terminal portion 285 for connection to the FPC 290 is included in a portion that is not overlapped with the pixel portion 284 over the substrate 201. Furthermore, the terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 11B. The pixel 284a includes the light-emitting element 120R, the light-emitting element 120G, and the light-emitting element 120B.

The pixel circuit portion 283 includes a plurality of pixel circuits 283a arranged periodically. The plurality of pixel circuits 283a may be placed in delta arrangement illustrated in FIG. 11B. With the delta arrangement that enables high-density arrangement of pixel circuits, a high-definition display device can be provided.

One pixel circuit 283a is a circuit that controls light emission of three light-emitting elements included in one pixel 284a. One pixel circuit 283a may be provided with three circuits for controlling light emission of one light-emitting element. For example, the pixel circuit 283a for one light-emitting element can include at least one selection transistor, one current control transistor (driving transistor), and a capacitor. In this case, a gate signal is input to a gate of the selection transistor, and a source signal is input to one of a source and a drain of the selection transistor. With such a structure, an active-matrix display device is achieved.

The circuit portion 282 includes a circuit for driving the pixel circuits 283a in the pixel circuit portion 283. For example, a gate line driver circuit, a source line driver circuit, or the like is preferably included. In addition, an arithmetic circuit, a memory circuit, a power supply circuit, or the like may be included.

The FPC 290 functions as a wiring for supplying a video signal, a power supply potential, or the like to the circuit portion 282 from the outside. In addition, an IC may be mounted on the FPC 290.

The display module 280 can have a structure in which the pixel circuit portion 283, the circuit portion 282, and the like are stacked below the pixel portion 284; thus, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have extremely high definition. For example, the pixels 284a are preferably arranged in the display portion 281 with a definition higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high definition, and thus can be suitably used for a device for VR, such as a head-mounted display, or a glasses-type device for AR. For example, even in the case of a structure in which the display portion of the display module 280 is seen through a lens, pixels of the extremely-high-definition display portion 281 included in the display module 280 are not seen even when the display portion is enlarged by the lens, so that display providing a high sense of immersion can be performed. Without limitation to the above, the display module 280 can also be suitably used for an electronic device having a comparatively small display portion. For example, the display module 280 can also be suitably used for a display portion of a wearable electronic device, such as a wristwatch.

At least part of this embodiment can be implemented in combination with the other embodiments described in this specification as appropriate.

### Embodiment 2

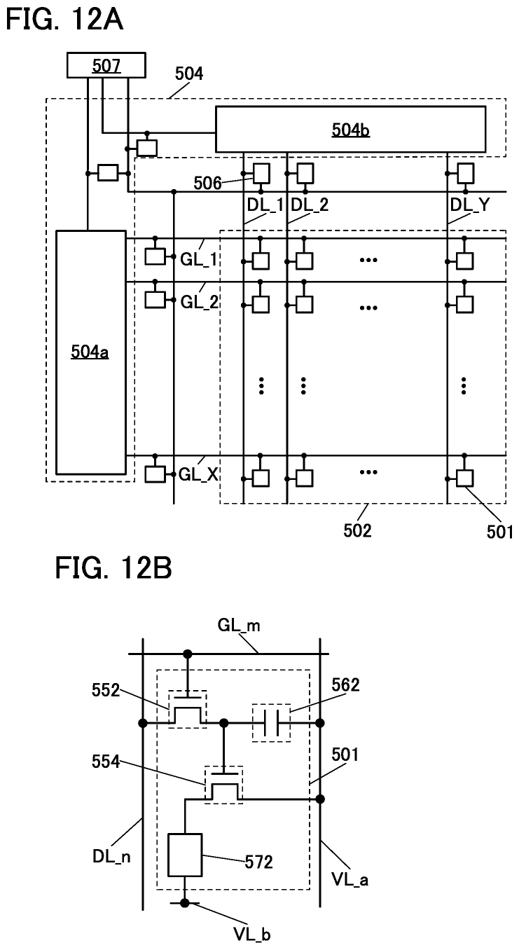

In this embodiment, a display device according to one embodiment of the present invention will be described using FIG. 12.

A display device illustrated in FIG. 12A includes a pixel portion 502, a driver circuit portion 504, protection circuits 506, and a terminal portion 507. Note that the display device according to one embodiment of the present invention may have a structure in which the protection circuits 506 are not provided.

The pixel portion 502 includes a plurality of pixel circuits 501 arranged in X rows and Y columns (X and Y each independently represent a natural number of 2 or more). Each of the pixel circuits 501 includes a circuit for driving a display element.

The driver circuit portion 504 includes driver circuits such as a gate driver 504a that outputs scan signals to gate lines GL_1 to GL_X and a source driver 504b that supplies data signals to data lines DL_1 to DL_Y. The gate driver 504a includes at least a shift register. In addition, the source driver 504b is formed using a plurality of analog switches, for example. Alternatively, the source driver 504b may be formed using a shift register or the like.

The terminal portion 507 refers to a portion provided with terminals for inputting power, control signals, image signals, and the like to the display device from external circuits.

The protection circuit 506 is a circuit that, when a potential out of a certain range is applied to a wiring to which the protection circuit 506 is connected, establishes continuity between the wiring and another wiring. The protection circuit 506 illustrated in FIG. 12A is connected to a variety of wirings such as gate lines GL that are wirings between the gate driver 504a and the pixel circuits 501 and data lines DL that are wirings between the source driver 504b and the pixel circuits 501, for example.

In addition, the gate driver 504a and the source driver 504b may each be provided over the same substrate as the pixel portion 502, or a substrate over which a gate driver circuit or a source driver circuit is separately formed (e.g., a driver circuit board formed using a single crystal semiconductor film or a polycrystalline semiconductor film) may be mounted on the substrate by COG or TAB (Tape Automated Bonding).

In particular, the gate driver 504a and the source driver 504b are preferably placed below the pixel portion 502.

In addition, the plurality of pixel circuits 501 illustrated in FIG. 12A can have a structure illustrated in FIG. 12B, for example.

The pixel circuit 501 illustrated in FIG. 12B includes transistors 552 and 554, a capacitor 562, and a light-emitting element 572. In addition, the data line DL_n, the gate line GL_m, a potential supply line VL_a, a potential supply line VL_b, and the like are connected to the pixel circuit 501.

Note that a high power supply potential VDD is applied to one of the potential supply line VL_a and the potential supply line VL_b, and a low power supply potential VSS is applied to the other of the potential supply line VL_a and the potential supply line VL_b. Current flowing through the light-emitting element 572 is controlled in accordance with a potential applied to a gate of the transistor 554, so that the luminance of light emitted from the light-emitting element 572 is controlled.

At least part of this embodiment can be implemented in combination with the other embodiments described in this specification as appropriate.

### Embodiment 3

A pixel circuit including a memory for correcting gray levels displayed by pixels that can be applied to a display device according to one embodiment of the present invention, and a display device including the pixel circuit will be described below.

### [Circuit Configuration]

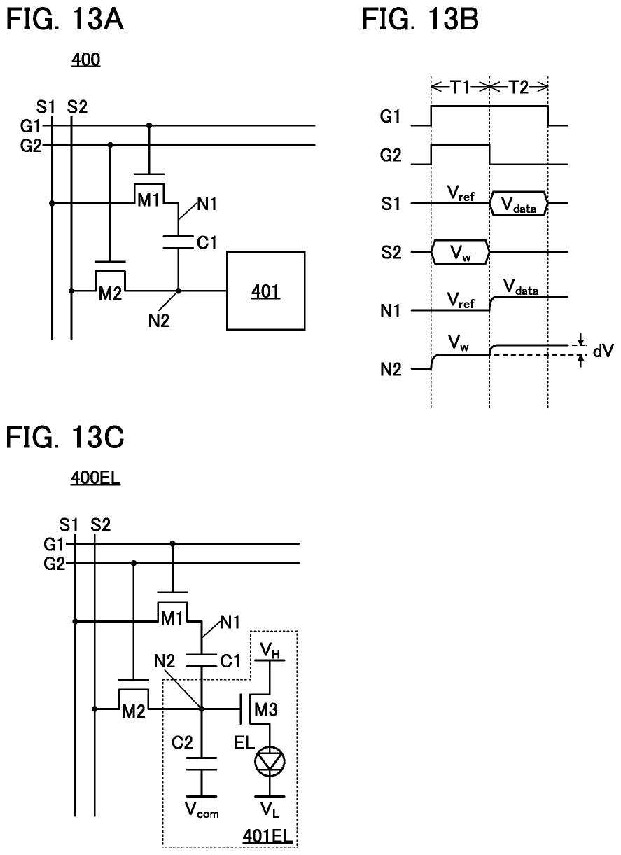

FIG. 13A illustrates a circuit diagram of a pixel circuit 400. The pixel circuit 400 includes a transistor M1, a transistor M2, a capacitor C1, and a circuit 401. In addition, a wiring S1, a wiring S2, a wiring G1, and a wiring G2 are connected to the pixel circuit 400.

In the transistor M1, a gate is connected to the wiring G1, one of a source and a drain is connected to the wiring S1, and the other of the source and the drain is connected to one electrode of the capacitor C1. In the transistor M2, a gate is connected to the wiring G2, one of a source and a drain is connected to the wiring S2, and the other of the source and the drain is connected to the other electrode of the capacitor C1 and the circuit 401.

The circuit 401 is a circuit including at least one display element. A variety of elements can be used as the display element, and typically, a light-emitting element such as an organic EL element or an LED element can be used. In addition, a liquid crystal element, a MEMS (Micro Electro Mechanical Systems) element, or the like can also be used.

A node that connects the transistor M1 and the capacitor C1 is denoted as a node N1, and a node that connects the transistor M2 and the circuit 401 is denoted as a node N2.

In the pixel circuit 400, the potential of the node N1 can be retained when the transistor M1 is set in an off state. In addition, the potential of the node N2 can be retained when the transistor M2 is set in an off state. Furthermore, when a predetermined potential is written to the node N1 through the transistor M1 with the transistor M2 being in an off state, the potential of the node N2 can be changed in accordance with displacement in the potential of the node N1 owing to capacitive coupling through the capacitor C1.

Here, the transistor employing an oxide semiconductor, which is illustrated in Embodiment 1, can be used as one or both of the transistor M1 and the transistor M2. Accordingly, owing to extremely low off-state current, the potentials of the node N1 and the node N2 can be retained over a long period. Note that in the case where the period in which the potential of each node is retained is short (specifically, the case where frame frequency is higher than or equal to 30 Hz, for example), a transistor employing a semiconductor such as silicon may be used.

### Driving Method Example

Next, an example of a method for operating the pixel circuit 400 is described using FIG. 13B. FIG. 13B is a timing chart of the operation of the pixel circuit 400. Note that for simplification of the description, the influence of various kinds of resistance such as wiring resistance, parasitic capacitance of a transistor, a wiring, or the like, the threshold voltage of the transistor, and the like is not taken into account here.

In the operation shown in FIG. 13B, one frame period is divided into a period T1 and a period T2. The period T1 is a period in which a potential is written to the node N2, and the period T2 is a period in which a potential is written to the node N1.

### [Period T1]

In the period T1, a potential for setting the transistor in an on state is applied to both the wiring G1 and the wiring G2. In addition, a potential V_{ref} that is a fixed potential is supplied to the wiring S1, and a first data potential V_{w} is supplied to the wiring S2.

The potential V_{ref} is applied from the wiring S1 to the node N1 through the transistor M1. In addition, the first data potential V_{w} is applied from the wiring S2 to the node N2 through the transistor M2. Accordingly, a potential difference V_{w}-V_{ref} is retained in the capacitor C1.

### [Period T2]

Next, in the period T2, a potential for setting the transistor M1 in an on state is applied to the wiring G1, and a potential for setting the transistor M2 in an off state is applied to the wiring G2. In addition, a second data potential V_{data} is supplied to the wiring Si. The wiring S2 may be supplied with a predetermined constant potential or brought into a floating state. The second data potential V_{data} is applied from the wiring S1 to the node N1 through the transistor M1. In that case, capacitive coupling due to the capacitor C1 changes the potential of the node N2 by a potential dV in accordance with the second data potential V_{data}. That is, a potential that is the sum of the first data potential V_{w} and the potential dV is input to the circuit 401. Note that although the potential dV is shown as a positive value in FIG. 13B, the potential dV may be a negative value. That is, the second potential V_{data} may be lower than the potential V_{ref}.

Here, the potential dV is roughly determined by the capacitance value of the capacitor C1 and the capacitance value of the circuit 401. In the case where the capacitance value of the capacitor C1 is sufficiently larger than the capacitance value of the circuit 401, the potential dV is a potential close to the second data potential V_{data}.

As described above, a potential to be supplied to the circuit 401 including the display element can be generated by a combination of two kinds of data signals in the pixel circuit 400, so that gray levels can be corrected in the pixel circuit 400.

In addition, in the pixel circuit 400, it is also possible to generate a potential exceeding the maximum potential that can be supplied to the wiring S1 and the wiring S2. For example, in the case where a light-emitting element is used, high-dynamic range (HDR) display or the like can be performed. Furthermore, in the case where a liquid crystal element is used, overdriving or the like can be achieved.

### Application Example

A pixel circuit 400EL illustrated in FIG. 13C includes a circuit 401EL. The circuit 401EL includes a light-emitting element EL, a transistor M3, and a capacitor C2.

In the transistor M3, a gate is connected to the node N2 and one electrode of the capacitor C2, one of a source and a drain is connected to a wiring for applying a potential V_{H}, and the other of the source and the drain is connected to one electrode of the light-emitting element EL. The other electrode of the capacitor C2 is connected to a wiring for applying a potential V_{com}. The other electrode of the light-emitting element EL is connected to a wiring for applying a potential V_{L}.

The transistor M3 has a function of controlling current to be supplied to the light-emitting element EL. The capacitor C2 functions as a storage capacitor. The capacitor C2 can be omitted when not needed.

Note that although a structure in which the anode side of the light-emitting element EL is connected to the transistor M3 is described here, the transistor M3 may be connected to the cathode side. In that case, the values of the potential V_{H} and the potential V_{L} can be changed as appropriate.

In the pixel circuit 400EL, a large amount of current can flow through the light-emitting element EL when a high potential is applied to the gate of the transistor M3, which enables HDR display or the like, for example. Moreover, a variation in electrical characteristics of the transistor M3 or the light-emitting element EL can also be corrected by supply of a correction signal to the wiring S1 or the wiring S2.

Note that the structure is not limited to the circuits illustrated in FIG. 13C, and a structure to which a transistor, a capacitor, or the like is further added may be employed.

At least part of this embodiment can be implemented in combination with the other embodiments described in this specification as appropriate.

### Embodiment 4

In this embodiment, structure examples of an electronic device to which the display device according to one embodiment of the present invention is applied will be described.

The display device and the display module according to one embodiment of the present invention can be applied to a display portion of an electronic device or the like having a display function. Examples of such an electronic device include a digital camera, a digital video camera, a digital photo frame, a cellular phone, a portable game machine, a portable information terminal, and an audio reproducing device, in addition to an electronic device with a comparatively large screen, such as a television device, a laptop personal computer, a monitor device, digital signage, a pachinko machine, or a game machine.

In particular, the display device and the display module according to one embodiment of the present invention can have high definition, and thus can be suitably used for an electronic device with a comparatively small display portion. Examples of such an electronic device include a watch-type or bracelet-type information terminal device (wearable device) and a wearable device worn on a head, such as a device for VR such as a head mounted display and a glasses-type device for AR.

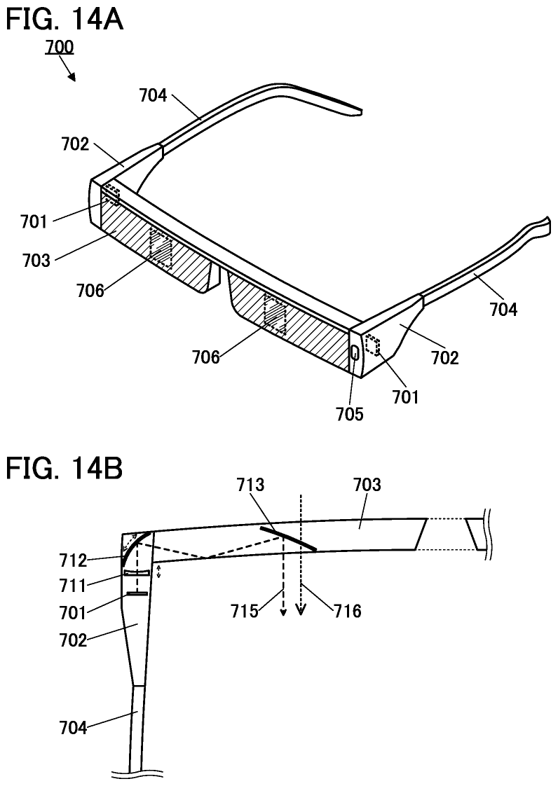

FIG. 14A is a perspective view of a glasses-type electronic device 700. The electronic device 700 includes a pair of display panels 701, a pair of housings 702, a pair of optical members 703, a pair of wearing portions 704, and the like.

The electronic device 700 can project an image displayed on the display panel 701 onto a display region 706 of the optical member 703. In addition, since the optical members 703 have a light-transmitting property, a user can see images that are displayed on the display regions 706 and are superimposed on transmission images seen through the optical members 703. Thus, the electronic device 700 is an electronic device capable of AR display.

One housing 702 is provided with a camera 705 capable of taking an image of what lies in front thereof. Although not illustrated, one of the housings 702 is provided with a wireless receiver or a connector to which a cable can be connected, so that a video signal or the like can be supplied to the housing 702. Furthermore, when the housing 702 is provided with an acceleration sensor such as a gyroscope sensor, the orientation of the user's head can be detected and an image corresponding to the orientation can be displayed on the display region 706. Moreover, the housing 702 is preferably provided with a battery because charging can be performed with or without a wire.

Next, a method for projecting an image on the display region 706 of the electronic device 700 is described using FIG. 14B. The display panel 701, a lens 711, and a reflective plate 712 are provided in the housing 702. In addition, a reflective surface 713 functioning as a half mirror is provided in a portion corresponding to the display region 706 of the optical member 703.

Light 715 emitted from the display panel 701 passes through the lens 711 and is reflected by the reflective plate 712 to the optical member 703 side. In the optical member 703, the light 715 is fully reflected repeatedly by end surfaces of the optical member 703 and reaches the reflective surface 713, so that an image is projected on the reflective surface 713. Accordingly, the user can see both the light 715 reflected by the reflective surface 713 and transmitted light 716 transmitted through the optical member 703 (including the reflective surface 713).

FIG. 14 shows an example in which the reflective plate 712 and the reflective surface 713 each have a curved surface. This structure can increase optical design flexibility and reduce the thickness of the optical member 703, compared to the case where the reflective plate 712 and the reflective surface 713 are flat. Note that the reflective plate 712 and the reflective surface 713 may be flat.

A component having a mirror surface can be used for the reflective plate 712, and the reflective plate 712 preferably has high reflectance. In addition, as the reflective surface 713, a half mirror utilizing reflection of a metal film may be used, but the use of a prism utilizing total reflection or the like can increase the transmittance of the transmitted light 716.

Here, the housing 702 preferably includes a mechanism for adjusting the distance or angle between the lens 711 and the display panel 701. This enables focus adjustment, zooming in/out of an image, or the like. One or both of the lens 711 and the display panel 701 are preferably configured to be movable in an optical-axis direction, for example.

In addition, the housing 702 preferably includes a mechanism capable of adjusting the angle of the reflective plate 712. The position of the display region 706 where images are displayed can be changed by changing the angle of the reflective plate 712. Thus, the display region 706 can be placed at the most appropriate position in accordance with the position of the user's eye.

The display device or the display module according to one embodiment of the present invention can be applied to the display panel 701. Thus, the electronic device 700 can perform display with extremely high definition.

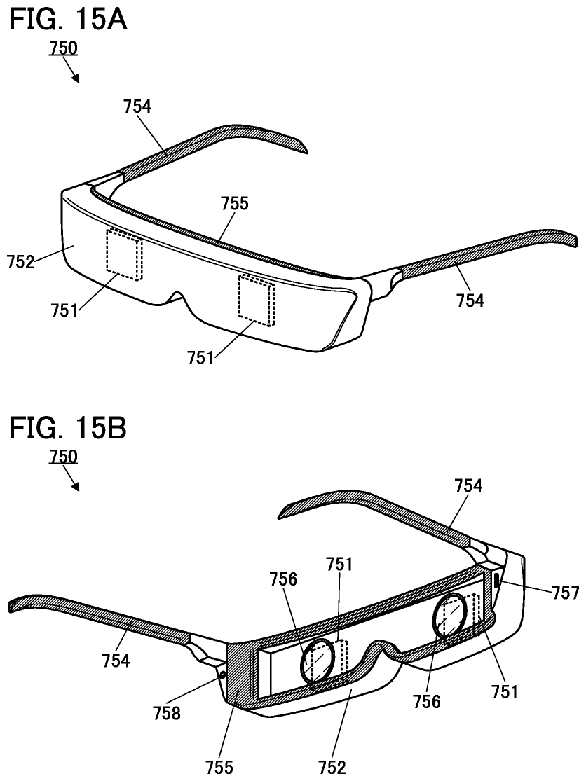

FIG. 15A and FIG. 15B are perspective views of a goggle-type electronic device 750. FIG. 15A is a perspective view illustrating the front surface, top surface, and left side surface of the electronic device 750, and FIG. 15B is a perspective view illustrating the back surface, bottom surface, and right side surface of the electronic device 750.

The electronic device 750 includes a pair of display panels 751, a housing 752, a pair of wearing portions 754, a shock-absorbing material 755, a pair of lenses 756, and the like. The pair of display panels 751 is positioned to be seen through the lenses 756 inside the housing 752.

The electronic device 750 is an electronic device for VR. A user wearing the electronic device 750 can see an image displayed on the display panel 751 through the lens 756. Furthermore, when the pair of display panels 751 displays different images, three-dimensional display using parallax can be performed.

In addition, an input terminal 757 and an output terminal 758 are provided on the back side of the housing 752. To the input terminal 757, a cable for supplying a video signal from a video output device or the like, power for charging a battery provided in the housing 752, or the like can be connected. The output terminal 758 can function as, for example, an audio output terminal to which earphones, headphones, or the like can be connected. Note that in the case where audio data can be output by wireless communication or sound is output from an external video output device, the audio output terminal is not necessarily provided.

In addition, the housing 752 preferably includes a mechanism by which the right and left positions of the lens 756 and the display panel 751 can be adjusted to the most appropriate positions in accordance with the position of the user's eye. Furthermore, the housing 752 preferably includes a mechanism for adjusting focus by changing the distance between the lens 756 and the display panel 751.

The display device or the display module according to one embodiment of the present invention can be applied to the display panel 751. Thus, the electronic device 750 can perform display with extremely high definition. This enables a user to feel a high sense of immersion.

The shock-absorbing material 755 is a portion in contact with the user's face (forehead, cheek, or the like). The shock-absorbing material 755 is in close contact with the user's face, so that light leakage can be prevented, which further increases the sense of immersion. A soft material is preferably used for the shock-absorbing material 755 so that the shock-absorbing material 755 is in close contact with the face of the user wearing the electronic device 750. For example, a material such as rubber, silicone rubber, urethane, or a sponge can be used. Furthermore, when a sponge or the like whose surface is covered with cloth, leather (natural leather or synthetic leather), or the like is used, a gap is less likely to be generated between the user's face and the shock-absorbing material 755, so that light leakage can be suitably prevented. Furthermore, using such a material is preferable because it has a soft texture and the user does not feel cold when wearing the device in a cold season, for example. The member in contact with user's skin, such as the shock-absorbing material 755 or the wearing portion 754, is preferably detachable because cleaning or replacement can be easily performed.

At least part of this embodiment can be implemented in combination with the other embodiments described in this specification as appropriate.

### Example

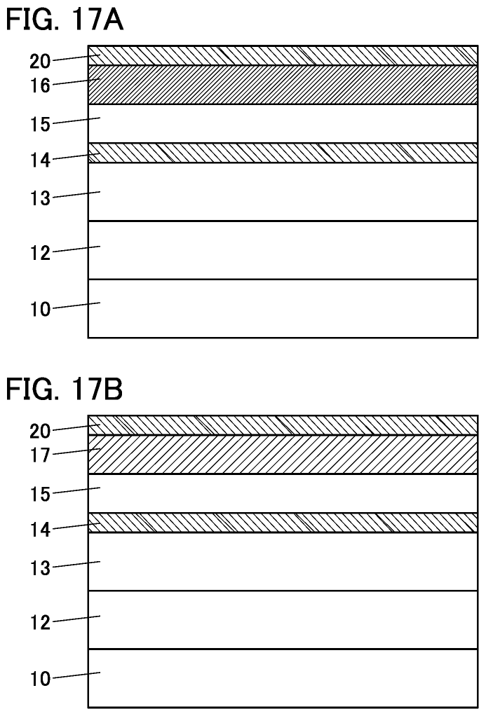

In this example, Sample A and Sample B each having a structure illustrated in FIG. 17A and Sample C and Sample D each having a structure illustrated in FIG. 17B were manufactured. Results of deuterium D and oxygen isotope (¹⁸O) concentrations of these samples evaluated by secondary ion mass spectrometry (SIMS) are shown.

The structure illustrated in FIG. 17A includes a silicon substrate 10, a silicon oxide film 12 over the silicon substrate 10, a silicon oxynitride film 13 over the silicon oxide film 12, a silicon nitride film 14 over the silicon oxynitride film 13, a silicon oxynitride film 15 over the silicon nitride film 14, a silicon oxynitride film 16 over the silicon oxynitride film 15, and a silicon nitride film 20 over the silicon oxynitride film 16.

In the structure illustrated in FIG. 17B, a silicon oxide film 17 is included instead of the silicon oxynitride film 16 in the structure illustrated in FIG. 17A.

First, a method for manufacturing Sample A to Sample D having the structures illustrated in FIG. 17A and FIG. 17B is described.

First, heat treatment was performed on the silicon substrate 10 at 950° C. in an HCl atmosphere, so that the silicon oxide film 12 with a thickness of 100 nm was formed.

Next, the silicon oxynitride film 13 with a thickness of 100 nm was deposited by a PECVD method.

Next, the silicon nitride film 14 with a thickness of 20 nm was deposited using a silicon target by an RF sputtering method. For deposition of the silicon nitride film 14, 20 sccm of an argon gas and 20 sccm of a nitrogen gas were used for deposition gases, deposition pressure was set to 3 mtorr, substrate temperature was set to room temperature, and the interval between the target and the substrate was set to 185 mm. For an RF power source, power was set to 1.5 kW.

Next, the silicon oxynitride film 15 with a thickness of 50 nm was deposited by a PECVD method.

Next, for Sample A and Sample B, the silicon oxynitride film 16 with a thickness of 50 nm was deposited by a PECVD method. Here, for deposition of the silicon oxynitride film 16, 200 sccm of a mixed gas containing deuterium (D₂) (D₂:Ar=10 sccm:190 sccm), 2.0 sccm of a SiH₄ gas, and 800 sccm of an N₂O gas were used as deposition gases.

Next, for Sample C and Sample D, the silicon oxide film 17 with a thickness of 50 nm was deposited by an RF sputtering method. Here, for deposition of the silicon oxide film 17, 25 sccm of an oxygen gas containing the oxygen isotope (¹⁸O) was used for a deposition gas.

Next, the silicon nitride film 20 with a thickness of 20 nm was deposited using a silicon target by an RF sputtering method. The silicon nitride film 20 was deposited under the same deposition conditions as the silicon nitride film 14.

Next, for Sample A and Sample C, heat treatment was performed in a nitrogen atmosphere at 400° C. for 8 hours.

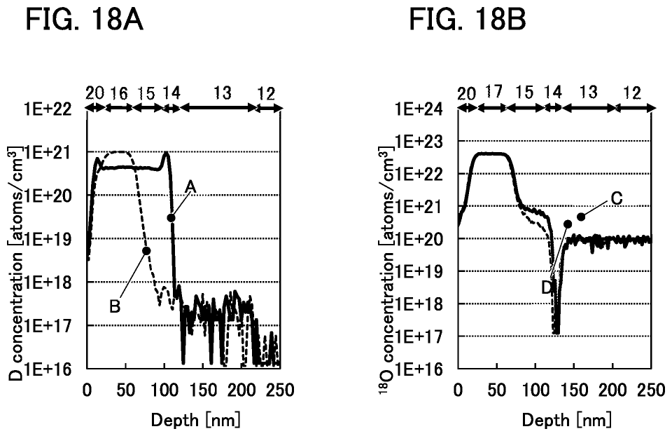

The deuterium D concentrations of Sample A and Sample B were evaluated using a SIMS analysis device, and the oxygen isotope (¹⁸O) concentrations of Sample C and Sample D were evaluated using the SIMS analysis device. Note that the analysis was conducted from the silicon substrate 10 side of each sample. FIG. 18A shows the SIMS analysis results of Sample A and Sample B, and FIG. 18B shows the SIMS analysis results of Sample C and Sample D.

FIG. 18A shows the deuterium D concentration profile of each sample in a depth direction. In FIG. 18A, a horizontal axis represents depth [nm] from a top surface of the silicon nitride film 20, and a vertical axis represents the deuterium D concentration [atoms/cm³] in the film.

As shown in FIG. 18A, in Sample A and Sample B, the deuterium D concentrations of layers below the silicon nitride film 14 are lower than 1.0×10¹⁸ [atoms/cm³]. That is, regardless of the presence of heat treatment at 400° C. for 8 hours after sample formation, diffusion of deuterium D contained in the silicon oxynitride film 16 into the layers below the silicon nitride film 14 is inhibited.

In addition, FIG. 18B shows the oxygen isotope (¹⁸O) concentration profile of each sample in a depth direction. In FIG. 18B, a horizontal axis represents depth [nm] from a top surface of the silicon nitride film 20, and a vertical axis represents the oxygen isotope (¹⁸O) concentration [atoms/cm³] in the film.

As shown in FIG. 18B, in Sample C and Sample D, the oxygen isotope (¹⁸O) concentrations of layers below the silicon nitride film 14 are lower than 1.0×10²¹ [atoms/cm³]. That is, regardless of the existence of heat treatment at 400° C. for 8 hours after sample formation, diffusion of an oxygen isotope (¹⁸O) contained in the silicon oxide film 17 into the layers below the silicon nitride film 14 is inhibited.

As described above, the silicon nitride film even with a thickness of 20 nm sufficiently functions as a barrier insulating film against hydrogen and oxygen. Using such a silicon nitride film for the insulating layer 122 or the insulating layer 124 described in the above embodiment can inhibit diffusion of hydrogen and oxygen into a light-emitting element or a semiconductor circuit in which an oxide semiconductor is used. In addition, as described in this example, the silicon nitride film functioning as a barrier insulating film functions sufficiently even when it is deposited at room temperature. That is, heat treatment at high temperatures during deposition is not required for a barrier insulating film described in this example. Therefore, such a barrier insulating film can be used for the insulating layer 124 without any degradation of the light-emitting element 120.

At least part of the structure, the method, and the like described in this example can be implemented in appropriate combination with embodiments and the like described in this specification.

### REFERENCE NUMERALS

C1: capacitor, C2: capacitor, DL_Y: data line, DL_1: data line, G1: wiring, G2: wiring, GL_X: gate line, GL_1: gate line, M1: transistor, M2: transistor, M3: transistor, N1: node, N2: node, RES1: resist, RES2: resist, RES3: resist, Si: wiring, S2: wiring, Ti: period, T2: period, 10: silicon substrate, 12: silicon oxide film, 13: silicon oxynitride film, 14: silicon nitride film, 15: silicon oxynitride film, 16: silicon oxynitride film, 17: silicon oxide film, 20: silicon nitride film, 100: display device, 101: substrate, 111: conductive layer, 111a: conductive layer, 1l1b: conductive layer, 114: conductive layer, 114B: conductive layer, 114G: conductive layer, 114R: conductive layer, 115: EL layer, 115f: EL layer, 115a: EL layer, 115b: EL layer, 115B: EL layer, 115Bf: EL layer, 115G: EL layer, 115Gf: EL layer, 115R: EL layer, 115Rf: EL layer, 116: conductive layer, 116f: conductive layer, 117: insulator, 120: light-emitting element, 120B: light-emitting element, 120G: light-emitting element, 120R: light-emitting element, 121: insulating layer, 122: insulating layer, 124: insulating layer, 125: insulating layer, 131: plug, 162: insulating layer, 163: insulating layer, 164: adhesive layer, 165B: coloring layer, 165G: coloring layer, 165R: coloring layer, 200: display device, 200A: display device, 200B: display device, 200C: display device, 200D: display device, 201: substrate, 202: substrate, 210: transistor, 211: conductive layer, 212: low-resistance region, 213: insulating layer, 214: insulating layer, 215: element isolation layer, 220: transistor, 221: semiconductor layer, 223: insulating layer, 224: conductive layer, 225: conductive layer, 226: insulating layer, 227: conductive layer, 228: insulating layer, 229: insulating layer, 230: transistor, 231: insulating layer, 232: insulating layer, 240: capacitor, 241: conductive layer, 242: conductive layer, 243: insulating layer, 251: conductive layer, 252: conductive layer, 253: conductive layer, 261: insulating layer, 261a: insulating layer, 261b: insulating layer, 262: insulating layer, 263: insulating layer, 264: insulating layer, 265: insulating layer, 271: plug, 271a: conductive layer, 271b: conductive layer, 272: plug, 273: plug, 274: plug, 280: display module, 281: display portion, 282: circuit portion, 283: pixel circuit portion, 283a: pixel circuit, 284: pixel portion, 284a: pixel, 285: terminal portion, 286: wiring portion, 290: FPC, 290b: source driver IC, 400: pixel circuit, 400EL: pixel circuit, 401: circuit, 401EL: circuit, 501: pixel circuit, 502: pixel portion, 504: driver circuit portion, 504a: gate driver, 504b: source driver, 506: protection circuit, 507: terminal portion, 552: transistor, 554: transistor, 562: capacitor, 572: light-emitting element, 700: electronic device, 701: display panel, 702: housing, 703: optical member, 704: wearing portion, 705: camera, 706: display region, 711: lens, 712: reflective plate, 713: reflective surface, 715: light, 716: transmitted light, 750: electronic device, 751: display panel, 752: housing, 754: wearing portion, 755: shock-absorbing material, 756: lens, 757: input terminal, 758: output terminal, 4411: light-emitting layer, 4412: light-emitting layer, 4413: light-emitting layer, 4420: layer, and 4430: layer.

1. A display device comprising:
a transistor over a substrate;
a first insulating layer over the transistor;
a second insulating layer over the first insulating layer;
a plug placed to be embedded in the first insulating layer and the second insulating layer; and
a light-emitting element over the second insulating layer, the light-emitting element comprising:
a first conductive layer,
an EL layer over the first conductive layer; and
a second conductive layer over the EL layer,
wherein the plug electrically connects one of a source and a drain of the transistor to the first conductive layer, and
wherein the second insulating layer has higher capability of inhibiting hydrogen diffusion than the first insulating layer.

2. The display device according to claim 1, wherein the second insulating layer contains nitrogen and silicon.

3. The display device according to claim 1,
wherein the second insulating layer includes a first layer and a second layer over the first layer,
wherein the first layer contains nitrogen and silicon, and
wherein the second layer contains oxygen and aluminum.

4. The display device according to claim 1,
wherein the second insulating layer includes a first layer and a second layer over the first layer,
wherein the first layer contains nitrogen and silicon, and
wherein the second layer contains oxygen and hafnium.

5. The display device according to claim 1,
wherein a third insulating layer is placed to cover the light-emitting element, and
wherein the third insulating layer has higher capability of inhibiting hydrogen diffusion than the first insulating layer.

6. The display device according to claim 5, wherein the third insulating layer is in contact with the second insulating layer in a region not overlapped with the light-emitting element.

7. The display device according to claim 5,
wherein the third insulating layer includes a third layer and a fourth layer over the third layer,
wherein the third layer contains oxygen and aluminum, and
wherein the fourth layer contains nitrogen and silicon.

8. The display device according to claim 1, wherein the EL layer covers a side surface of the first conductive layer.

9. The display device according to claim 1,
wherein an insulator is placed between the EL layer and the first conductive layer,
wherein the insulator has an opening over the first conductive layer, and
wherein the EL layer is in contact with the first conductive layer in the opening.

10. The display device according to claim 1, wherein the first conductive layer has a property of reflecting visible light.

11. The display device according to claim 1, wherein the second conductive layer has a property of transmitting and reflecting visible light.

12. The display device according to claim 1,
wherein the substrate is a silicon substrate, and
wherein the transistor includes silicon in a channel formation region.

13. The display device according to claim 1,
wherein an oxide semiconductor film is provided over the substrate, and
wherein the transistor includes the oxide semiconductor film in a channel formation region.
